(19) United States
(12) Patent Application Publication
(10) Pub. No.: US 2026/0226608 A1
(43) Pub. Date: Aug. 6, 2026

(54) ELECTRONIC DEVICES AND CIRCUITS

(71) Applicant: PRAGMATIC SEMICONDUCTOR LIMITED, Cambridge (GB)

(72) Inventors: Richard PRICE, Cambridge (GB); Feras ALKHALIL, Cambridge (GB)

(21) Appl. No.: 19/154,986

(22) PCT Filed: Feb. 26, 2024
(86) PCT No.: PCT/GB2024/050517

§ 371 Date: Aug. 8, 2025

(30) Foreign Application Priority Data
Feb. 27, 2023 (GB) 2302862.4

(51) Int. Cl. C23C 16/04; H10D 30/01; H10P 14/24

(52) U.S. Cl. CPC C23C 16/04; H10D 30/031; H10P 14/24

(57) ABSTRACT

A method of manufacturing at least a first electronic device (1, 1a) comprising a first plurality of components (11, 12, 13, 131, 132, 14, 15, 16) is disclosed. The method comprises: providing a substrate (2) to support the first electronic device, at least during its manufacture; and selectively depositing over a first limited (bounded) portion (LP1, 201) of the substrate, by atomic layer deposition (ALD), a first thin film (T1) of conductive, semiconductive, resistive, or dielectric material, the first thin film providing at least one of the first plurality of components.

### FIELD OF THE INVENTION

The present invention relates to electronic devices and circuits, and to their methods of manufacture. Certain embodiments relate to thin film devices suitable for incorporation in flexible circuits, and to flexible circuits or circuit portions themselves.

### BACKGROUND TO THE INVENTION

A number of techniques are known for the deposition of thin films (^{~}1 nm to ^{~}1 μm in thickness) of semiconducting materials, insulating materials and conducting materials. Some of these have found application in the manufacture of thin film transistors (TFTs) employing metal oxide semiconductor channel materials. In general, sputtering—a form of physical vapour deposition (PVD)—may be used to deposit blanket layers of the semiconductor, insulator and/or conductor materials, since it is a relatively fast and low cost technique, however, thermal annealing is often required post-deposition to obtain good film quality. Atomic Layer Deposition (ALD) has also been used for this purpose, producing a high quality conformal blanket film at low temperatures but at a relatively low speed.

More recently, spatial ALD (sALD) has been developed, enabling savings in time and cost. Referencing a chapter in ‘Chemical vapour deposition for nanotechnology’ by IntechOpen, conventional ALD (temporal ALD) achieves deposition by sequentially exposing the substrate to precursors through short pulses which are separated by purge steps. sALD differs from conventional ALD in that the precursors are continuously supplied in different locations and are kept physically separated by inert gas zones. In one example, the metal oxide semiconductor (IGZO) and gate dielectric (Al₂O₃) layers for a TFT display backplane were deposited in an integrated sALD process. Other semiconductors, such as ZnO, SnO and Cu₂O, have also been deposited using sALD. However much of the emphasis for sALD has been on large area deposition of blanket films.

Spatial or area selectivity is very important in the production of integrated circuits (ICs). In the context of thin film TFT-based ICs, the dimensions and characteristics of all devices, e.g. TFTs, resistors, capacitors, electrodes, wiring, and so on, must be very carefully controlled. Typically, such spatial selectivity is enabled by some form of lithographic patterning, masking and etching of a blanket layer of material. This approach can result in low efficiency of material utilisation, since much of the area of a deposited layer may be removed during etching. Furthermore, it is desirable to include devices having a range of properties in an IC. For example, circuit designs may be improved if they can incorporate transistors having a number of different conductivities, breakdown voltages, switching speeds, etc.

### SUMMARY OF THE INVENTION

Certain embodiments of the invention therefore aim to address at least one of the problems associated with the prior art.

According to a first aspect of the invention there is provided a method of manufacturing at least a first electronic device (1, 1a) comprising a first plurality of components (11, 12, 13, 131, 132, 14, 15, 16) (e.g. a thin film transistor comprising a source terminal, a drain terminal, a semiconductive channel connecting the source terminal to the drain terminal, a gate terminal to which a voltage may be applied to control a conductivity of the semiconductive channel, and a gate dielectric insulating the gate terminal from the semiconductive channel), the method comprising:
providing a substrate (2) to support the first electrode device, at least during its manufacture;
selectively depositing over a first limited (bounded) portion (LP1, 201) (i.e. not all) of said substrate, by atomic layer deposition (ALD), a first thin film (T1) (e.g. a first bounded thin film; an island; a bounded island having a perimeter and not covering all of the substrate) of conductive, semiconductive, resistive, or dielectric material, said first thin film providing at least one of said first plurality of components (e.g. at least one of: said source terminal; said drain terminal; said gate terminal; said semiconductive channel; and said gate dielectric).

Thus, in certain embodiments, the first thin film is selectively deposited over only a limited or bounded portion of the substrate (or surface thereof), and hence the first thin film is itself bounded. It may have a boundary, edge, or perimeter within the footprint (or overall extent) of the substrate, and be surrounded by a portion or portions of the substrate (e.g. an annular portion, completely enclosing or encircling the first thin film) not under (or covered by) the first thin film.

The thin film may be formed directly or indirectly on a surface of the substrate—for example, directly on an “upper” surface of the substrate, or at least partly on or over at least one other entity, layer, body, or structure formed on the upper surface. Thus, at least a portion (and in certain embodiments, all) of the thin film may be formed in direct contact with a surface of the substrate, and in alternative embodiments at least a portion (and in certain embodiments, all) of the thin film may not be in direct contact with a surface of the substrate. Alternatively, the substrate may itself be a multi-layer, multi region, and/or multi-element/component structure, and a surface of the substrate on which the thin film may be directly formed may be planar, non-planar, uniform, or non-uniform.

A second aspect provides a method of manufacturing an electronic circuit comprising a first plurality of electronic devices, each device comprising a respective plurality of components, the method comprising:
providing a substrate to support the first plurality of electronic devices (e.g. to support the entire circuit), at least during their manufacture;
selectively depositing over a first limited (bounded) portion (i.e. not all) of said substrate, by atomic layer deposition (ALD), a first thin film (e.g. an island) of conductive, semiconductive, resistive, or dielectric material, said first thin film providing at least one of said respective plurality of components of each of said first plurality of electronic devices.

In certain embodiments of this second aspect, the electronic circuit further comprises a second plurality of electronic devices, each comprising a respective plurality of components, and the method further comprises:
providing said substrate to support the second plurality of electronic devices (e.g. to support the entire circuit), at least during their manufacture;
selectively depositing over a second limited (bounded) portion (i.e. not all) of said substrate, by atomic layer deposition (ALD), a second thin film (e.g. an island) of conductive, semiconductive, resistive, or dielectric material, said second thin film providing at least one of said respective plurality of components of each of said second plurality of electronic devices.

Thus, certain aspects of the invention make use of differing islands (e.g. the first and second thin films) of relatively low spatial resolution to support different populations (e.g. the first and second pluralities of devices) of relatively higher resolution devices. Certain embodiments utilize the option of patterning (e.g. lithographic patterning) of semiconductive and/or dielectric layers or islands (deposited by ALD) to separate devices in the same island from each other (e.g. as shown in FIG. 24).

In certain embodiments of the second aspect, said first plurality of electronic devices comprises a first plurality of thin film transistors, TFTs, each thin film transistor comprising a respective source terminal, a respective drain terminal, a respective semiconductive channel connecting the source terminal to the drain terminal, a respective gate terminal to which a voltage may be applied to control a conductivity of the semiconductive channel, and a respective gate dielectric insulating the gate terminal from the semiconductive channel,
wherein said first thin film provides at least one of said source terminal, said drain terminal, said gate terminal, said semiconductive channel, and said gate dielectric of each of the first plurality of TFTs.

The first thin film in certain embodiments of the second aspect (and other aspects) is a thin film of semiconductive material and provides the semiconductive channels of each of the first plurality of TFTs.

Another aspect provides a method of manufacturing an electronic circuit comprising a first electronic device, comprising a first plurality of components, and a second electronic device, comprising a second plurality of components, the method comprising:
providing a substrate to support the first and second electronic devices, at least during their manufacture;
selectively depositing over a first limited (bounded) portion (i.e. not all) of said substrate, by atomic layer deposition (ALD), a first thin film (e.g. an island) of conductive, semiconductive, resistive, or dielectric material, said first thin film providing at least one of said first plurality of components of said first electronic device; and
selectively depositing over a second limited (bounded) portion (i.e. not all) of said substrate, by atomic layer deposition (ALD), a second thin film (e.g. an island) of conductive, semiconductive, resistive, or dielectric material, said second thin film providing at least one of said second plurality of components of said second electronic device.

Another aspect provides an electronic device, a plurality of electronic devices, or an electronic circuit manufactured using a method in accordance with any other aspect.

Another aspect provides an electronic circuit comprising a first plurality of electronic devices, each device comprising a respective plurality of components, the electronic circuit comprising:
a first thin film (e.g. an island) of conductive, semiconductive, resistive, or dielectric material, said first thin film providing at least one of said respective plurality of components of each of said first plurality of electronic devices.

### BRIEF DESCRIPTION OF DRAWINGS

Embodiments of the invention will now be described with reference to the accompanying drawings, of which:

FIG. 1 is a schematic representation of a head unit which may be used in embodiments of the invention;

FIG. 2 is a schematic representation of the formation of a first thin film T1 in an embodiment of the invention;

FIG. 3 is a schematic representation of the manufacture of an electronic device;

FIG. 4 illustrates a range of substrates that may be used in devices and methods embodying the invention;

FIG. 5 illustrates steps in a method of forming part of a thin film device;

FIG. 6 illustrates steps in a method of forming a thin film to provide a semiconductive channel of a thin film transistor embodying the invention;

FIG. 7 illustrates another method of forming a thin film to provide a semiconductive channel of a thin film transistor;

FIG. 8 illustrates another method of forming a thin film to provide a semiconductive channel of a transistor;

FIG. 9 illustrates steps in the formation of a thin film transistor embodying the invention;

FIG. 10 illustrates steps in a method of manufacturing a top gate thin film transistor;

FIG. 11 illustrates general techniques for processing thin films or portions thereof in methods embodying the invention;

FIG. 12 illustrates steps in the formation of a bottom gate thin film transistor embodying the invention;

FIG. 13 illustrates steps in a method of forming a top gate thin film transistor in a method embodying the invention;

FIG. 14 illustrates steps in the formation of a bottom gate thin film transistor embodying the invention;

FIG. 15 illustrates steps in the formation of part of a circuit including two top gate thin film transistors in a method embodying the invention;

FIG. 16 illustrates steps in the formation of part of a circuit comprising two bottom gate thin film transistors in a method embodying the invention;

FIG. 17 illustrates steps in the formation of part of a circuit comprising two bottom gate thin film transistors;

FIG. 18 illustrates steps in the formation of part of a circuit embodying the invention and including a bottom gate thin film transistor and a top gate thin film transistor;

FIG. 19 illustrates steps in the formation of a plurality of top gate transistors, sharing a semiconductive island;

FIG. 20 illustrates steps in the formation of a plurality of bottom gate transistors, sharing a semi conductive island;

FIG. 21 illustrates steps in the formation of a plurality of transistors, one being a top gate device, one being a bottom gate device, and sharing a semi conductive island;

FIG. 22 illustrates a variety of electronic devices embodying the invention and which may be manufactured using methods embodying the invention;

FIG. 23 illustrates steps in the manufacture of a circuit comprising a plurality of electronic devices;

FIG. 24 illustrates steps in the manufacture of another circuit comprising a plurality of electronic devices; and

FIGS. 25 and 26 illustrate more electronic devices embodying the invention and which may be manufactured using methods embodying the invention.

### DETAILED DESCRIPTION OF EMBODIMENTS

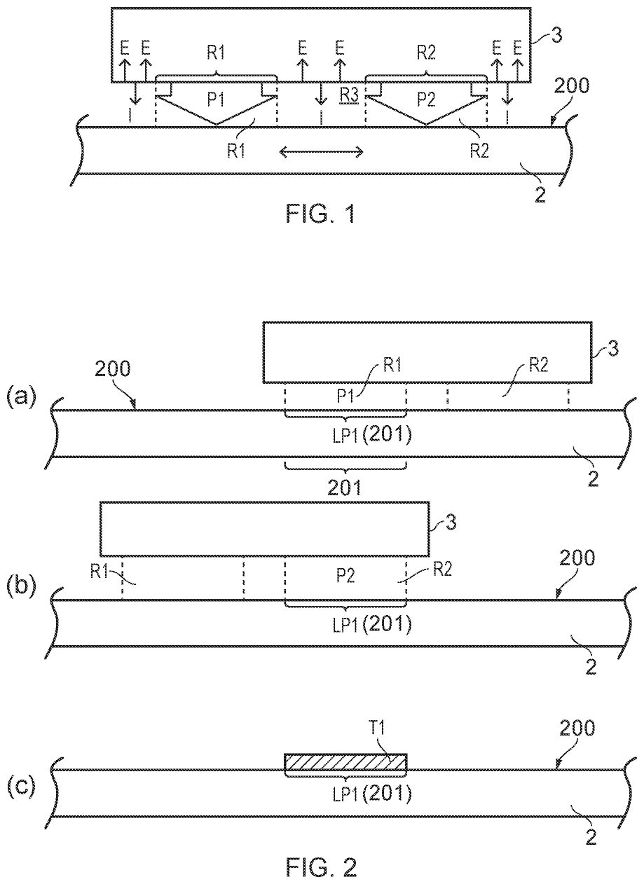

Referring now to FIG. 1, this is a highly schematic representation of a spatial ALD (sALD) head unit 3 which may be used in embodiments of the invention to form one or more thin films of material on or over a substrate 2. The head unit is configured to enable thin films of material to be deposited, by ALD, on a substrate in an atmospheric pressure technique; in other words there is no need for the head unit to be provided inside a sealed chamber. Generally, the head unit is arranged to supply first precursor, which may also be referred to as a reactant, P1 to a first spatial region or zone R1 adjacent the head unit, and a second precursor P2 to a second spatial region or zone R2 also adjacent the head unit, but spatially separated from the first region or zone. The supply of the precursors to these two regions is by means of suitably arranged ports or other supply means, details of which are not shown in the figure for clarity. The head unit is also arranged to supply inert gas (I) to a third region adjacent the head unit and separating the first and second regions, and also to further regions of the head unit outside (surrounding) the first and second regions. The supply of inert gas is also by means of suitable ports or other supply means. The head unit also includes a plurality of exhaust ports E which are arranged to extract gaseous material away from the substrate 2. In the figure substrate 2 is shown positioned next to (adjacent to) the head unit. The head unit thus uses one or more curtains of inert gas and suitably arranged extraction to keep the ALD precursors separate, and to ensure that precursor material is confined to the desired spatial regions and does not spread or escape from the general volume sandwiched between the head unit and substrate surface. In this example the head unit is dimensioned such that the first and second spatial regions are smaller than the substrate itself, but in certain alternative embodiments each of the regions to which precursors are applied may be larger than the substrate, in which case patterning of the substrate with inhibitor material will in general be required in order to produce thin films by atomic layer deposition having dimensions suitably small for the formation of electronic device features.

Referring now to FIG. 2, this shows a head unit such as that illustrated in FIG. 1 being used to form a first thin film T1 on a substrate. The thin film is to be formed over a first limited portion 201 of the substrate, not all of the substrate, and in this example is to be formed directly on a corresponding first limited portion LP1 of an upper surface 200 of the substrate. However, in alternative embodiments, at least part of the thin film may be formed indirectly on the substrate surface, for example if the substrate already has another layer, component, structure, element, or body formed on its upper surface. To form the thin film T1, as shown in FIG. 2a, the head unit 3 is first positioned such that first spatial region R1 is above (or, in other words, over or adjacent to) the first limited portion of the substrate 201, and the first limited portion LP1 of substrate surface is in (or, in other words, below, under, in contact with, or adjacent to) the first spatial region R1 and exposed to precursor P1. The head unit is maintained in this position for a suitable length of time. Subsequently, as shown in FIG. 2b, the head unit is moved such that the second spatial region R2 is above (over, adjacent to) the first limited portion of substrate 201, and the surface limited portion LP1 is in (below, under, in contact with, adjacent to) the second spatial region R2 and exposed to precursor P2. The head unit is maintained in this position for a suitable length of time. Thus, surface portion LP1 is alternately exposed to the first and second precursors P1 and P2, and this results in the formation, by ALD, of a thin film of material T1 over the first limited portion 201. The steps shown in FIGS. 2a and 2b may be repeated, so as to build up the thickness of T1.

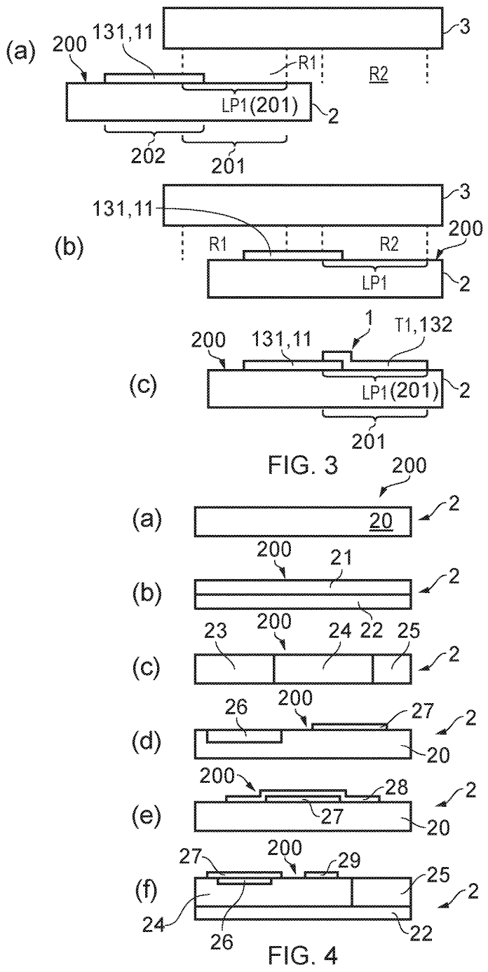

Referring now to FIG. 3, this shows the formation of a thin film in another embodiment. Here, as shown in FIG. 3a, the substrate 2 already has a first device component 131,11 formed on its upper surface. This first component is positioned over a second limited portion 202 of the substrate. The first component may, for example, be a conductive terminal 11 of a device (formed by sALD, by lithography (involving deposition and patterning), or by any other suitable technique). Alternatively, the first component may be a layer of semiconductive material 131 (again formed by sALD, by lithography (involving deposition and patterning), or by any other suitable technique), providing a component of an electronic device such as a transistor, a resistor, a capacitor, an inductor, or a diode. Generally, the first device component may be a component of a wide variety of devices, and may be formed of conductive, semiconductive, resistive, or dielectric material. As shown in FIG. 3a, the head unit 3 is first positioned relative to the substrate such that the first spatial region R1 is over a first limited portion 201 of the substrate, precursor P1 is supplied to R1, and thus a portion of the first device component surface and an adjacent portion of substrate surface LP1 are exposed to the first precursor for a suitable length of time. Next, the head unit 3 is positioned such that R2 is over the first limited portion 201, and P2 is supplied to R2. The alternate application of precursors P1 and P2 results in a thin film T1 of material being formed over the substrate portion 201, that thin film T1 partly overlapping the first device element 131, 11, and partly formed in direct contact with a surface 200 of the substrate. Again, steps 3a and 3b may be repeated to build up the thickness of thin film T1 by ALD. FIG. 3c shows the eventual structure produced. In certain embodiments, the device 1 formed may be a diode, comprising a first semiconductive element 131 and a second semiconductive element 132, that second element 132 being provided by the thin film T1 formed by sALD. In certain embodiments, the device 1 formed may be device, or a portion of an electronic device, such as a transistor, a resistor, a capacitor or an inductor. For example, the device 1 may be a portion of a resistor comprising a first conductive contact element (131) and a first resistive element (132). In another example, the device 1 may be a portion of a transistor comprising a first semiconductive element (131) and a first conductive contact element (132). Also, the structure shown in FIG. 3c may be further processed to remove at least the thin film T1 material overlapping the first element 131, 11 (and optionally remove some of the material of the first element 131, 11) and so planarize the structure.

Referring now to FIG. 4, the substrate, on or over which at least one thin film may be formed in embodiments of the invention, may take a variety of forms. The substrate 2 may also be described as a support, supporting member, supporting element, supporting entity, or supporting structure. FIG. 4 illustrates a variety of substrates which may be used in devices and methods embodying the invention. FIG. 4a shows a substrate 2 in the form of the uniform body 20 of material, and which may be rigid or flexible. The substrate has a flat upper surface 200. In FIG. 4b, the substrate has a multilayer structure, comprising an upper layer 21 and a lower layer 22. FIG. 4c illustrates another substrate that has a multi-component structure, comprising a laterally arranged sequence of substrate elements 23, 24, 25. FIG. 4d shows another substrate which has structure, with a body of material 20 having an additional substrate member 27 formed on its upper surface, and a portion of that member 20 being doped to form a doped region 26 on an adjacent portion of the body's upper surface. Thus, in this example the overall substrate upper surface 200 is not planar and not uniform. FIG. 4e shows an alternative substrate, with a plurality of substrate features or elements 27, 28 formed on/over an upper surface of a substrate body 20. Those substrate features 27, 28 may be circuit features or components, and/or device features of one or more devices to be formed on the substrate, for example by ALD. FIG. 4f shows another substrate having structure, comprising a base layer 22 supporting lateral elements 24 and 25, with lateral element 24 including a doped portion 26, and a further plurality of substrate features 27 and 29 formed over lateral element 24.

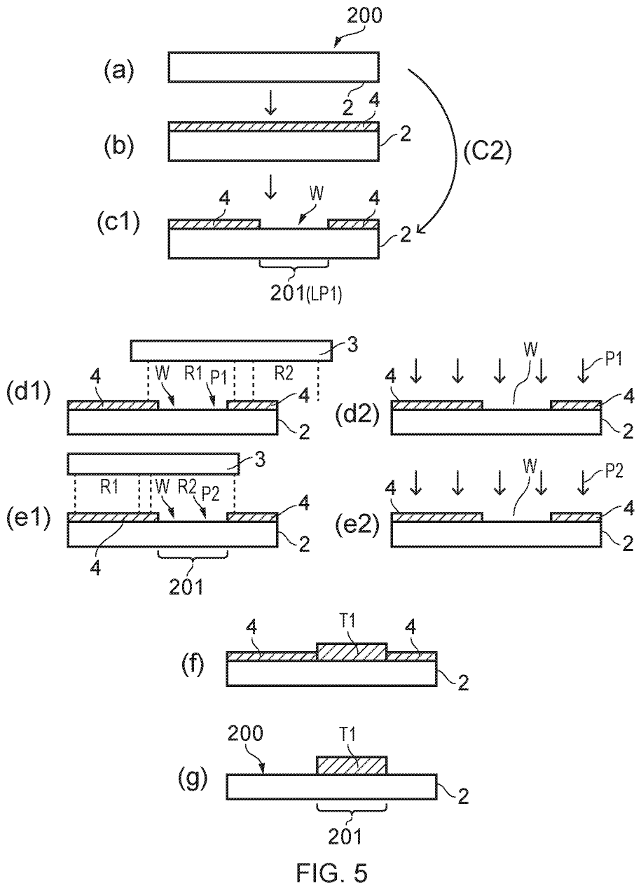

It will be appreciated that FIGS. 2 and 3 illustrate techniques in which the size (extent) of the thin film produced by atomic layer deposition generally corresponds to the size (e.g. footprint) of the first and second spatial regions defined by the head unit. Referring now to FIG. 5, this shows an alternative technique to form a thin film over a substrate region 201, and which can be used to manufacture smaller thin film islands and/or smaller device features.

Generally, FIG. 5 illustrates spatial (or area) selectivity, enabled by depositing (printing) patterned inhibitor materials prior to the ALD or sALD deposition, preventing chemisorption of the ALD precursor materials. The spatial resolution achievable with this approach may be of the order of several um. In step 5a a substrate 2 is provided. This substrate may take any one of the various forms described elsewhere in the specification, and may have structure, but for simplicity this figure represents the substrate as just a single rectangle. In Step 5b a uniform layer of inhibitor material 4 is formed over the entire upper surface of the substrate 2. Then, in Step 5c1 the layer of inhibitor material 4 is patterned using a suitable technique (such as lithography) to expose at least one selected (and limited) portion of the substrate upper surface, on which the thin film is to be formed by ALD. In this example, the patterning of the inhibitor material has formed a window W, through to the substrate upper surface, and the shape and size of the window will define the shape and size of the subsequent thin film. The window W is thus formed over the first limited portion of substrate 201. As an alternative to blanket deposition and then patterning of inhibitor material, the patterned layer of inhibitor material may be formed directly, by a suitable technique, such as printing, and this is represented by step 5c2.

Application of precursors to form the thin film may then be achieved using a SALD head, and/or by application on a uniform, whole-substrate basis.

FIG. 5d1 and 5e1 illustrate use of an sALD head for the thin film formation. Here, the spatial regions R1 and R2 defined by the sALD head 3 are the same size as one another, and larger than the window W (in at least one dimension). In FIG. 5d1, the head 3 is positioned such that the window W is under (or below, in, adjacent to, in contact with) the first spatial region R1 and the exposed portion of substrate surface is in contact with first precursor material P1 for a desired length of time. Then, in step 5e1, the head unit is positioned such that the second spatial region is over the window, and the second precursor P2 is supplied to the material previously exposed to P1, again for a desired length of time. The inhibitor material prevents/inhibits formation of material by ALD around the window, so that the thin film T1 is only formed inside the window. Steps 5d1 and 5e1 may be repeated, to gradually build up the thickness of T1. Thus, the use of patterned inhibitor material has enabled the sALD head unit to be used to produce a thin film having at least one dimension smaller than at least one dimension of the head unit spatial regions R1 and R2.

As an alternative to the spatially localised sALD approach of FIG. 5d1 and 5e1, FIG. 5d2 and 5e2 illustrate alternate application of precursors P1 and P2 on a uniform, whole-substrate basis. Again, the thin film T1 is formed only inside the window W, steps 5d2 and 5e2 may be repeated, to build up thickness, and the resultant structure is shown in FIG. 5f. In certain embodiments, the remaining inhibitor material may then be removed, as shown in FIG. 5g.

It will be appreciated that sALD head units having large first and second spatial regions may be used to manufacture certain embodiments, with inhibitor material optionally being used to produce small islands and/or device features. However, certain embodiments may utilise, or be formed using, much smaller sALD head units, for example microreactor head units (which may be described as sALD print heads) that allow features as small as 400 μm wide, or smaller, to be produced directly (i.e. without requiring any use of patterned inhibitor material). Additionally, such micro-head units may also be used in conjunction with lithographic techniques to produce even smaller features, with the use of sALD micro-heads providing the advantage that the formation of thin films can be achieved at atmospheric pressure, and no ALD chamber being required.

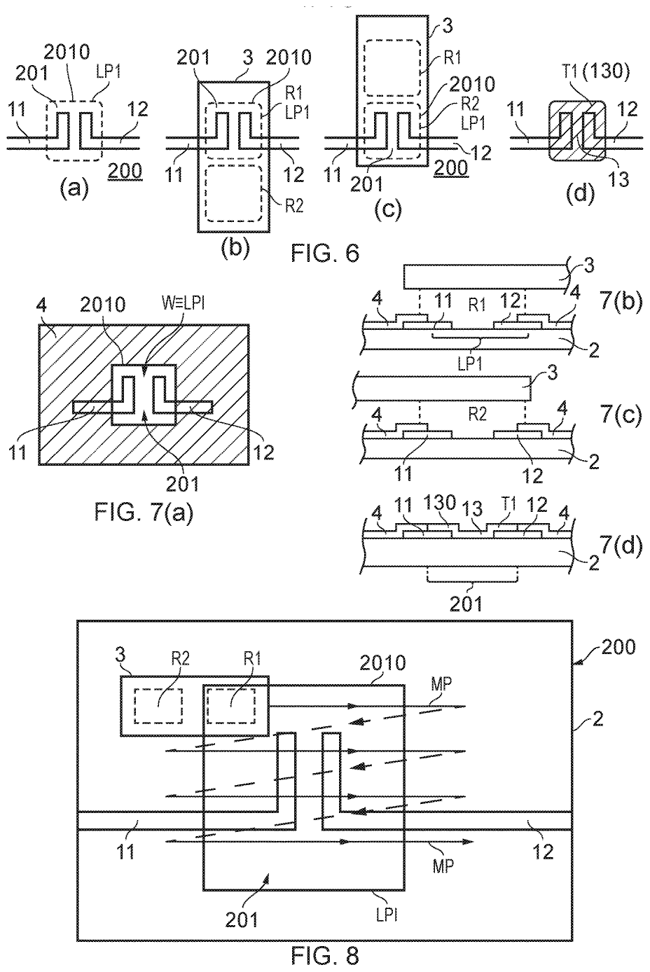

FIG. 6 illustrates the use of a micro-head unit 3, to form a thin film T1 (a bounded thin film, having a boundary or perimeter) or island of semiconductive material to provide the semiconductive channel of a thin film transistor TFT. As shown in FIG. 6a, source 11 and drain 12 terminals of the TFT are formed on a substrate surface 200. The semiconductor material is to be formed over the first limited portion 201 of substrate, on LP1 of the upper surface, having perimeter/boundary 2010. In FIG. 6b, the micro-head unit 3 is positioned with region R1 over LP1, and in this example the thin film corresponds to the smallest feature size directly formable (without lithography) by the head. Thus, LP1 is first exposed to precursor P1. Then, the head is moved to position R2 over LP1, and exposes LP1 to P2. A thin film T1, 130 of semiconductor material is thus formed by ALD, and this thin film provides the controllable semiconductive channel 13 connecting the source 11 and drain 12 terminals. Steps b and c can be repeated to build up thin film thickness. FIG. 6d illustrates the resultant structure, prior to formation of a gate dielectric and gate terminal to complete the TFT.

FIG. 7 illustrates use of a micro head in conjunction with lithography. Again, the device being produced is a TFT, and FIG. 7a shows a substrate comprising source and drain terminals already provided. A patterned layer of inhibitor material 4 has been formed, with a window defining the position and extent of the thin film of semi-conductive material to be deposited. In this example, as shown in FIG. 7b, the first spatial region R1 of the head unit 3 is larger than the window W, and is first positioned over the window, and over the first limited portion LP1 of the substrate upper surface. Thus, the first precursor is provided to a portion of the substrate upper surface, that portion including parts of the source and drain terminals which are not covered by patterned inhibitor. The head unit is then moved relative to the substrate to bring the second spatial region R2 over the window, and in this manner a thin film T1 of semiconductive material is built up inside the window, that thin film partly overlapping the source and drain terminals and providing a semi conductive channel 13 connecting those terminals. The patterned inhibitor material can be left on the structure in certain embodiments, as shown in FIG. 7. It will be appreciated that although the micro head 3 may enable small device features to be created directly, its use in conjunction with patterned inhibitor material can enable even smaller islands of material, and hence even smaller device features, to be formed in certain embodiments.

Referring now to FIG. 8, this shows an example in which the first limited portion 201 of substrate over which a thin film is to be formed is larger than the first and second spatial regions R1, R2 of the head unit 3. In order to form the thin film over the entirety of LP1, the head unit is positioned at the starting point illustrated in the figure, then moved along a movement path MP at a suitable speed. In this example the movement path is a scanning path. In this way, each part or portion of the region LP1 is alternately exposed to the first and second precursors P1, P2, and a thin film (of semiconductor material in this example) is built up over region 201. The head unit may follow the movement path just once, or multiple times to build up thickness of the film by ALD. In effect, the head unit 3 is being used as a print head, to print or effectively paint the layer of material over the desired substrate portion.

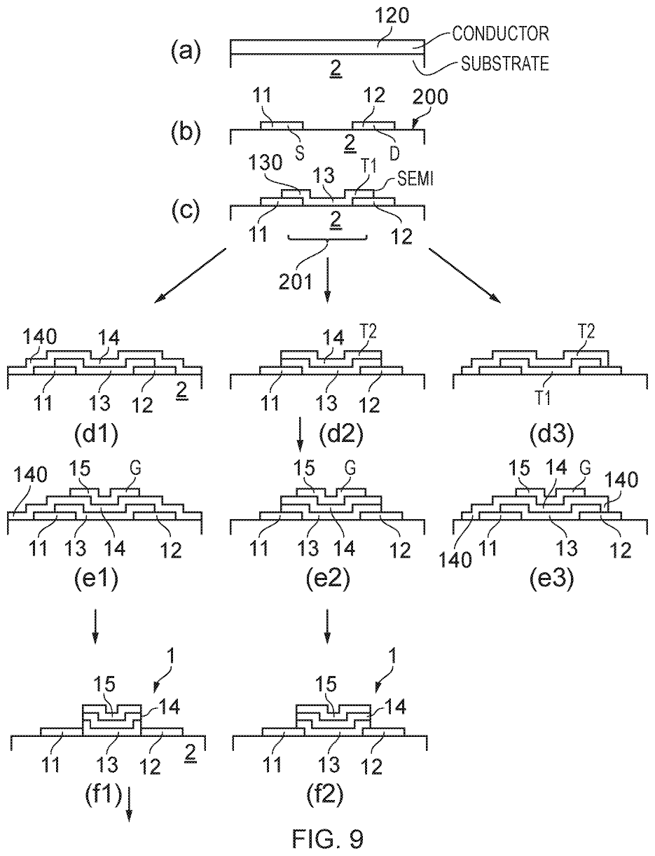

Referring now to FIG. 9, this illustrates the formation of a single top gate transistor. In a first step, 9a, a substrate is provided and a uniform layer of conductive material 120 is provided over at least a portion of the substrate upper surface (in other words, a blanket conductor is formed). Next, 9b, the layer of conductive material is patterned using any suitable technique to form source and drain terminals 11, 12. Then, 9c, a spatially-limited (or, in other words, bounded) thin film T1 of semiconductive material 130 is formed by spatial atomic layer deposition sALD, in accordance with one of the techniques described elsewhere in the specification. That thin film is formed over a first limited portion 201 of the substrate such that it partially overlaps the source and drain terminals and provides a semiconductive channel 13 connecting those terminals. The figure then illustrates three alternative branches that the method may take.

In the first branch, as illustrated by d1, a blanket layer of dielectric material 140 is formed (e.g. deposited), that layer providing the gate dielectric 14 of the TFT. Then, in e1, an aligned gate 15 (aligned with the gap between the source and drain terminals) is formed by a suitable technique. Finally, the gate 15 may be used as a mask in the removal of some of the semiconductor and dielectric materials, to produce the structure in FIG. 9f1. However, that final stage is optional, and in alternative embodiments at least some, or all, of the dielectric layer 140 not under the gate may not be removed (e.g. the gate may not be used as a mask), such that it still covers at least parts, or all, of the source and drain terminals, for example. The dielectric may, for example, provide an advantage of insulating the source and drain (or other features in their “layer”) from overlying layers, and/or may be useful for forming vias, e.g. to connect to the source and/or drain terminals).

In the second branch, a second thin film (a second island) T2, of dielectric material, is formed over the first thin film by sALD, that second thin film having the same footprint (size) as the first thin film (as shown in FIG. 9d2). A gate terminal is then formed over the dielectric island (9e2), and that gate terminal 15 may, optionally, then be used as a mask to produce the structure in 9f2.

In the third branch, in 9d3 a second thin film T2, of dielectric material, is again formed by sALD over the first film T1, but has a different shape and/or size. Thus, the second film T2 is formed over a different portion of the substrate to that over which the first film T1 is formed. In FIG. 9e3, an aligned gate is formed over the dielectric, but is not used subsequently as a mask; the first and second thin films T1, T2 are left as originally formed (e.g. there is no removal of semiconductive material).

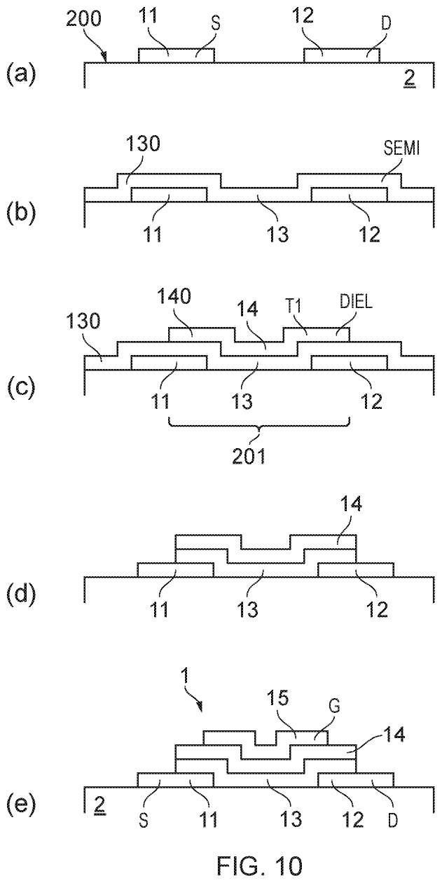

FIG. 10 illustrates steps in another method of manufacturing a top gate TFT. In a first step (10a) source and drain terminals 11, 12 are formed on a substrate 2. In the second step (10b) a blanket layer of semiconductor material 130 is formed over the source and drain terminals. In the third step (10c) a thin film T1 or island of dielectric material 140 is formed (by sALD, over a first limited portion of the substrate 201) over the semiconductor layer and provides the gate dielectric 14 of the device. In a fourth step (10d) the island T1 of dielectric material 140 is used as a mask to remove some of the material of the blanket layer of semiconductor 130. Finally an aligned gate terminal is formed over the gate dielectric 14.

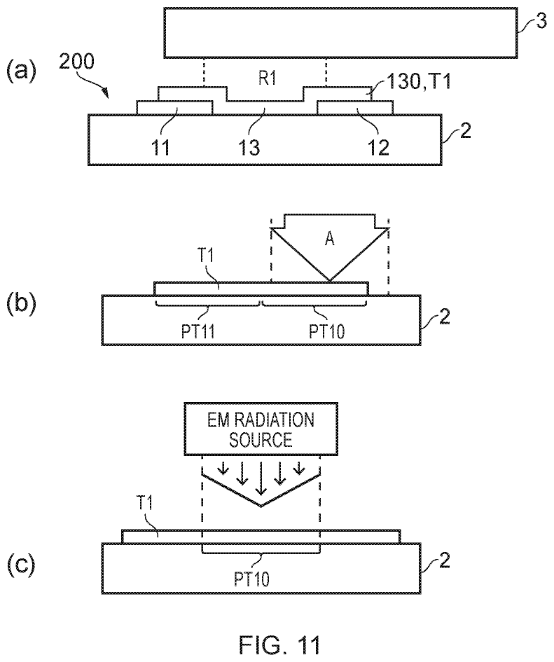

FIG. 11 illustrates in very general terms how thin films of material formed in methods embodying the invention may be processed before continuing to form further thin films or layers or components of their respective devices. FIG. 11a shows part of an electronic device that has been formed on a substrate 2. Again the substrate is shown in simple form, but in embodiments the substrate may have any of the forms described elsewhere in the specification, and for example may have structure. In this simplified example, source and drain terminals 11, 12 have been formed and a thin film or island T1 of semiconductor material 130 has been formed to connect those underlying terminals. A head unit 3 has been positioned above the structure such that a central portion of the thin film T1, that will provide the semiconductive channel of the TFT, is in or under spatial region R1. The head unit 3 can then be used to supply suitable material to region R1, and so expose that central portion of the deposited semiconductor to that material, and alter at least one of its electrical and or electronic properties. FIG. 11b shows an alternative technique in which a selected portion PT10 of a thin film T1 of material (formed by spatial atomic layer deposition in an embodiment) of the invention is being processed. The processing is illustrated generally by arrow A, is arranged such that at least one property of the portion PT10 is changed, and may take a wide variety of forms, as will be appreciated. For example the surface of portion PT10 may be modified by one or more techniques such as thermal annealing, laser annealing, plasma treatment, self-assembled monolayers, reactive ion etching, ozone UV treatment, and doping. FIG. 11c illustrates the general provision of electromagnetic radiation from a suitable source to a selected portion of a thin film T1 to selectively alter at least one property of that portion.

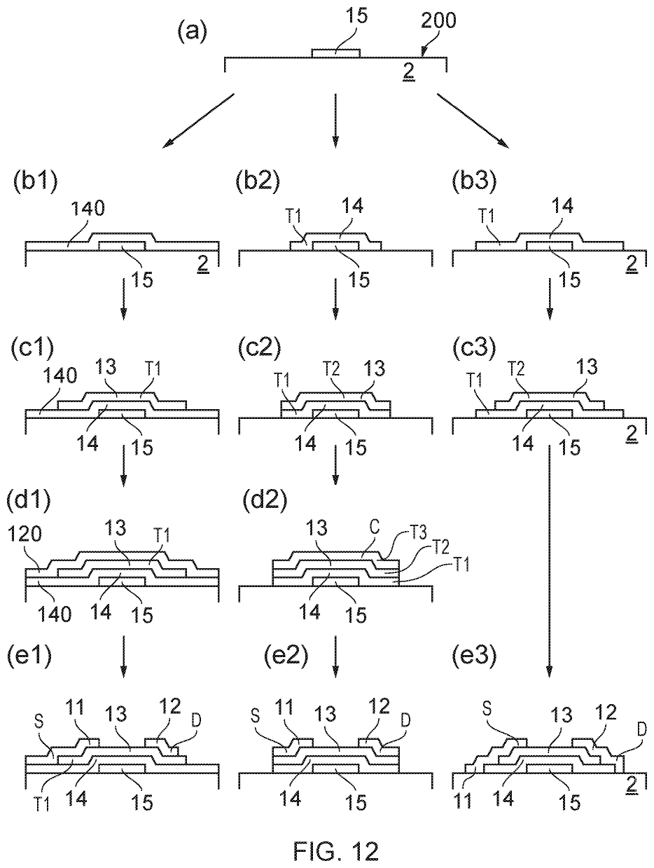

FIG. 12 illustrates steps in the manufacture of a thin film transistor having a bottom gate. In a first step, 12a, A gate terminal or bottom gate 15 is formed by any suitable technique on the substrate 2. Again the substrate may have any of the forms described in this specification. The method then has three branches.

In the first branch, a blanket layer of dielectric material 140 is formed over the gate 15 (12b1) and provides the gate dielectric 14 of the device. Then (12c1) a thin film or island T1 of semiconductor material 13 is formed by sALD over the dielectric, that thin film being formed over a first limited portion of the substrate. Next (12d1) a blanket layer of conductor material 120 is formed over the semiconductor island T1 and then finally (12e1) that blanket layer of conductor is patterned to form source and drain terminals 11, 12 of the device.

In the second branch, rather than depositing a blanket layer of dielectric material, a first thin film T1 of dielectric material is formed by ALD over a limited portion of the substrate (as shown in 12b2) and provides gate dielectric 14. Next, (12c2) a second thin film T2, this time of semiconductor material is deposited directly on the first thin film, by sALD and over the same limited portion of underlying substrate, and provides the semiconductive channel 13. Then (12d2) a third thin film T3, of conductive material C, is deposited directly on the second thin film by sALD over the same substrate portion. Thus, the three thin films are formed directly on top of one another, in a stack, each by sALD, and each having the same footprint. Finally, the top thin film T3 of conductor is patterned to form the source and drain terminals 11, 12. The three stacked thin films or islands T1, T2, T3 thus form a plurality of components 11, 12, 13, 14, and 15 of the device 1, in this example a TFT.

In the third branch, a first thin film or island T1 of dielectric is again formed over the gate (12b3) by sALD, and a second thin film T2, of semiconductor is formed on the dielectric by sALD, but has a different footprint (see 12c3). Finally, the source and drain terminals 11, 12 are formed, each by sALD of a respective further thin film of conductive material, to yield the structure shown in FIG. 12e3.

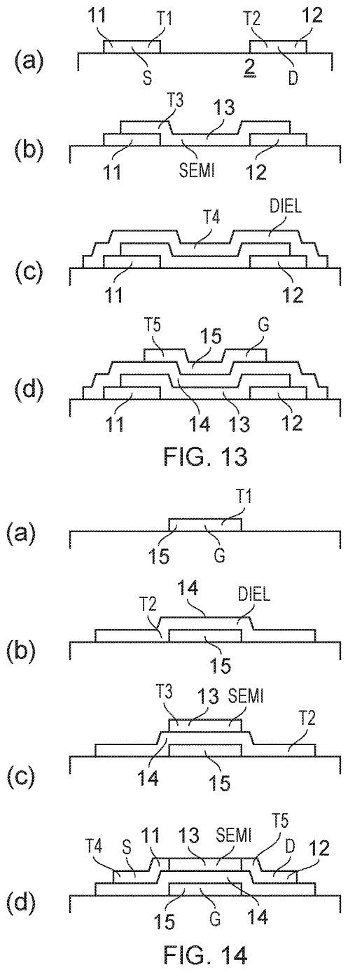

FIG. 13 illustrates steps in the manufacture of another top gate thin film transistor, this time using an all sALD approach. In a first step (13a) separate thin films T1 and T2 of conductive material are formed on a substrate by sALD, over different respective portions of the substrate. Next (13b) a third thin film T3, in the form of an island of semiconductive material, is formed by sALD, to provide the TFT channel 13. In certain embodiments, the semiconductive material (or at least a portion of it) may be processed, optionally, to alter at least one of its electrical or electronic properties after deposition. Then, whether there has been optional processing or not, a fourth thin film T4, of dielectric material is formed by sALD over the underlying structure (13c), and finally a gate terminal 15 is formed by depositing a further thin film T5 by sALD, on top of the dielectric.

FIG. 14 illustrates a corresponding all-sALD technique for manufacturing a bottom gate TFT. In a first step, 14a, the bottom gate terminal 15 is formed by depositing a first thin film of conductive material T1. A second thin film T2 is then deposited to provide the gate dielectric, a third thin film T3 is deposited to provide the semiconductive channel material, and fourth and fifth thin films of conductor are deposited (all by sALD) to provide the source and drain terminals. In the illustrated example, the source and drain terminals do not overlap the layer T3 of semiconductive material, but in alternative examples, one or both of the source and drain may overlap the semiconductive material. It will be appreciated that in certain embodiments, in addition to the illustrated steps, one of more of the deposited thin films (or a portion or portions thereof) may be subjected to processing to alter at least one property, before forming any further layer, film, or component.

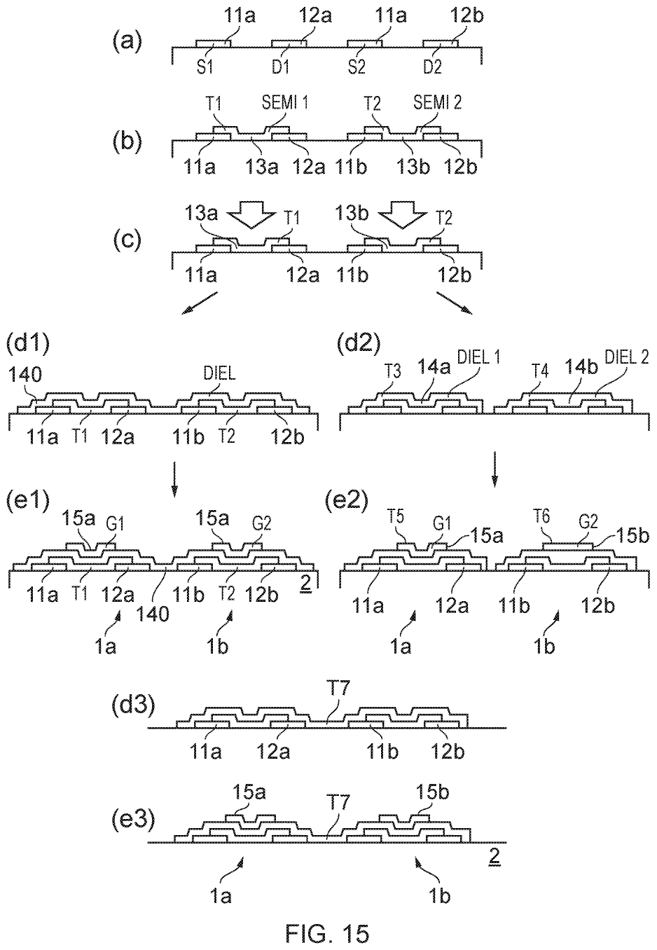

FIG. 15 illustrates steps in the formation of two top gate TFTs 1a, 1b (and so illustrates steps in the formation of a circuit comprising those two devices), with separate semiconductor islands, using a method embodying the invention. In a first step (15a) source (11a, 11b) and drain (12a, 12b) terminals of each device are formed on a substrate by any suitable technique, such as those described anywhere in this specification. Then (15b) first and second thin films (islands) T1, T2 of semiconductive material are formed by sALD over different respective portions of the substrate, each to partially overlap and connect its respective terminals and provide a respective semiconductive channel 13a, 13b. In step 15c, one or each of the islands T1, T2 is optionally processed to alter its semiconductive properties. As each island is deposited separately, the two islands may thus be formed of the same or different materials, may have the same or different extents, may have the same or different thicknesses and/or other dimensions, and generally may have properties/dimensions in common, or have properties/dimensions that differ, as desired. This gives the circuit designer/manufacturer considerable freedom.

The method then has three branches.

In a first branch, a blanket layer of dielectric 140 is formed over both devices (d1), and then separate aligned gates 15a, 15b (also labelled G1 and G2 respectively, for first and second gates) may be formed (15e1). Thus, in this first branch, the devices have separate semiconductor islands, but a common dielectric.

In a second branch, separate third and fourth thin films (islands) T3, T4 of dielectric material are deposited by sALD, one for each device (see 15d2), and then gates 15a, 15b are formed (optionally as separate islands T5, T6 by sALD too, or by any other appropriate method described anywhere in this specification). Thus, the two dielectric islands (and/or the two conductive islands) may be formed of the same or different materials, may have the same or different extents, may have the same or different thicknesses and/or other dimensions, and generally may have properties/dimensions in common, or have properties/dimensions that differ, as desired.

In a third branch, a shared (common) island T7 of dielectric material is formed by sALD over the separate semiconductor islands, and gate terminals may then be formed by any suitable technique (including any disclosed in this specification).

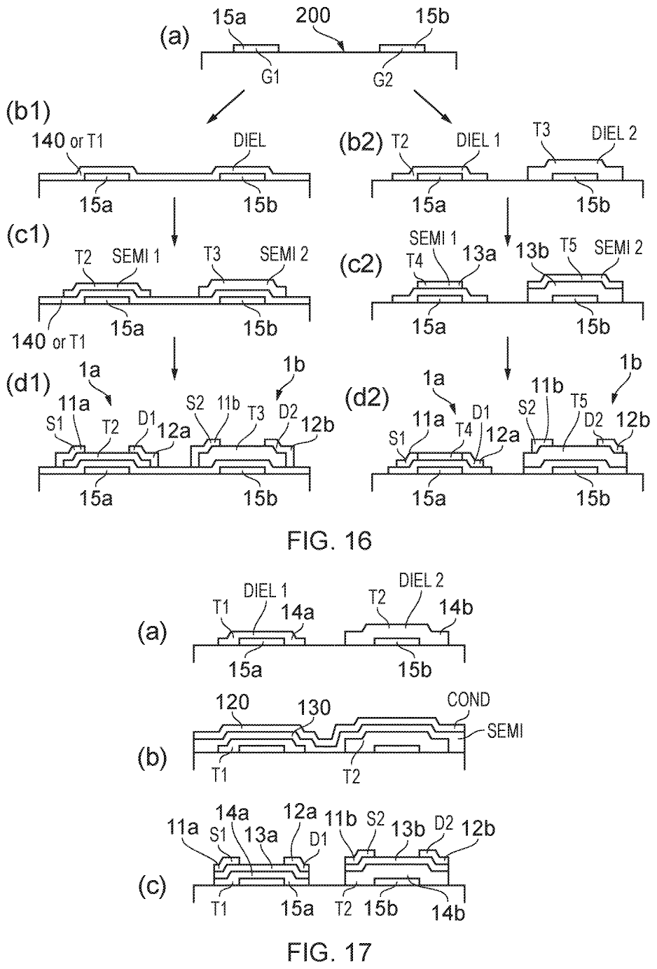

FIG. 16 illustrates steps in the manufacture of two transistors, both bottom gate transistors, with separate semiconductive islands. In the first step, respective bottom gates are provided on a substrate by any suitable technique, such as those described anywhere in this specification. The method then has two branches.

In the first branch, a layer of dielectric material 140 is formed so as to cover both of the underlying bottom gates (b1). This layer of dielectric material 140 may be a blanket layer of dielectric material formed over substantially all of the substrate surface. In alternative embodiments, this layer of dielectric material may be a shared or common island of dielectric material in the form of a thin film T1 formed by sALD. Next (c1) separate thin films or islands T2, T3 of semiconductor material are formed on the dielectric layer, each over its respective underlying gate terminal 15a, 15b. Finally (d1), respective source and drain terminals are formed by any suitable technique, including any of the techniques disclosed in this specification.

In the second branch, separate thin films or islands T2, T3 of dielectric material are formed by sALD, each over its respective gate 15a, 15b (16b2). Then, further separate thin films or islands T4, T5 of semiconductor are formed by sALD (c2), and then respective pairs of source and drain terminals S1/11a, D1/12a and S2/11b, D2/12b are formed (d2). Although in FIG. 16d2 source and drain terminals S1 and D1 are shown to make contact with only the edges of semiconductor channel T4 of TFT 1a, they may alternatively make contact with both the edges and the upper surface of semiconductor channel T4, such that they partially overlie it.

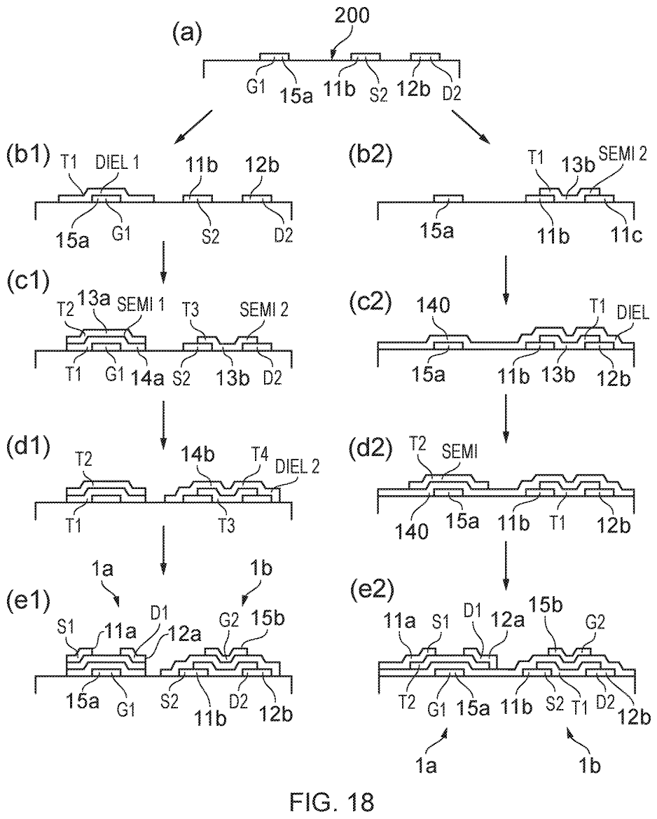

FIG. 17 illustrates steps in the manufacture of a circuit comprising two transistors, both bottom gate, with separate dielectrics but sharing the same semiconductor material. In a first step (a) respective gates are provided on a substrate, and separate gate dielectric islands (thin films) T1 and T2 are formed by sALD. They may thus be formed from the same or different materials, may have one or more properties in common, and or one or more differing properties. Next, blanket layers of semiconductive material 130 and conductive material 120 are formed (b), and then patterned (c) to form the source and drain terminals and semiconductive channels of the separate devices.

FIG. 18 illustrates steps in the manufacture of a circuit comprising two transistors, one being a top gate transistor and the other being a bottom gate transistor, those transistors having separate semiconductive islands. In a first step (a) the bottom gate 15a of the first transistor and the source and drain terminals 11b, 12b of the second transistor are formed on a substrate. The method then has two branches.

In the first branch, a first thin film or island of dielectric material T1 is formed over the bottom gate 15a by sALD over a first limited portion of the substrate. Next (c1), a second thin film, of semiconductor, T2 is formed over the first thin film (and has the same footprint) by sALD (to provide the channel of the first TFT 1a), and a third thin film T3 of semiconductor is formed by sALD over a second, separate limited portion of the substrate (to provide the channel of the second TFT 1b). Then (d1) a fourth thin film T4, of dielectric, is formed over the third thin film by sALD. Finally, upper source and drain terminals 11a, 12a of the first device 1 and top gate 15b of the second device are formed (e.g. by deposition and patterning of a common layer of conductor (lithography), or by sALD of respective further thin films or islands of conductive material).

In the second branch, a first thin film T1 of semiconductor is deposited by sALD to provide the channel of the second TFT 1b (b2). Then, a shared layer or island of dielectric 140 is formed, either by blanket deposition or formation of a shared island by sALD (c2). Next, a second thin film T2 of semiconductor is formed (by sALD) to provide the channel of the first TFT 1a (d2), and finally upper source and drain terminals 11a, 12a of the first TFT 1a and top gate 15b of the second TFT 1b are formed (e.g. by deposition and patterning of a common layer of conductor (lithography), or by sALD of respective further thin films or islands of conductive material).

It will be appreciated that the two transistors formed via the first branch can have the same or different semiconductor materials and the same or different dielectric materials. In the two devices formed via the second branch, the two transistors share the same dielectric material but can have the same or different semiconductor materials.

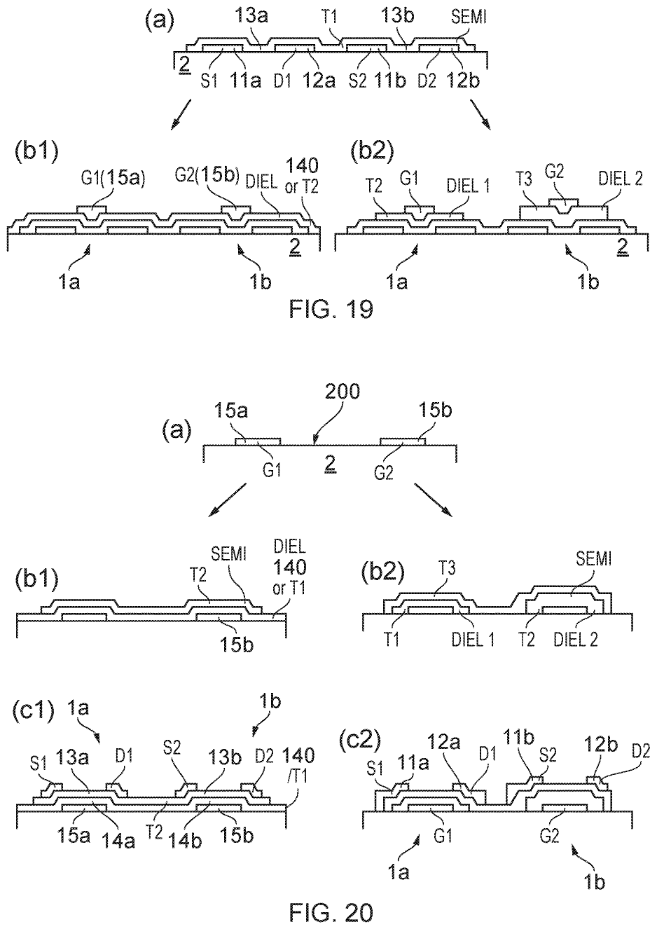

Referring now to FIG. 19 this illustrates steps in the formation of a circuit comprising a plurality of top gate transistors sharing a semiconductor island. In this example, the respective source and drain terminals of each device are provided on a substrate (or as part of a substrate structure). A common layer (thin film T1) or island of semiconductor material has been formed over the source and drain terminals so as to provide the channels 13a, 13b of each TFT. The method then has two branches.

In a first branch, a common or shared layer of dielectric material is provided, either by a blanket-deposited layer, or by a thin film T1 formed by sALD over a limited portion of the substrate. Upper gate terminals 15a, 15b are then formed via any suitable technique (including any disclosed in this specification), and one or both of those gate terminals may be aligned with their respective underlying source and drain terminals (so as to have no, or minimal, overlap and so reduce parasitic capacitances).

In the second branch (FIG. 19b2) separate dielectric thin film islands T2, T3 are formed by sALD, and then the gate terminals G1, G2 may be formed by any suitable technique (including by sALD).

It will be appreciated that the plurality of transistors manufactured via the first branch in FIG. 19 share the same semiconductor material and the same dielectric material. In contrast, the plurality of transistors formed via the second branch of FIG. 19 share the same semiconducting material, but may have different dielectric materials.

Referring now to FIG. 20, this illustrates steps in the formation of a circuit comprising a plurality of bottom gate transistors, sharing a semiconductor island. In a first step (20a) the gate terminals 15a, 15b (G1, G2) of each TFT 1a, 1b are provided on a substrate (or as part of a substrate structure). The method then has two branches.

In a first branch, a common or shared layer of dielectric material is provided, either by a blanket-deposited layer 140, or a thin film T1 formed by sALD over a limited portion of the substrate. The shared dielectric covers both bottom gates. A common thin film or island T2 of semiconductor is formed by sALD to provide the channels of each device, and source and drain terminals are then formed by any suitable technique, to arrive at the structure of FIG. 20c1.

In a second branch, separate dielectric islands T1, T2 are formed by sALD, then a common island of semiconductor material T3 is formed by sALD. Finally, source and drain terminals are then formed by any suitable technique, to arrive at the structure of FIG. 20c2.

It will be appreciated that the plurality of devices formed via the first branch illustrated in FIG. 20 have the same dielectric material and the same semiconductive material as each other. In contrast, the plurality of devices formed by the second branch illustrated in FIG. 20 have the same semiconductive material but may have different dielectric materials.

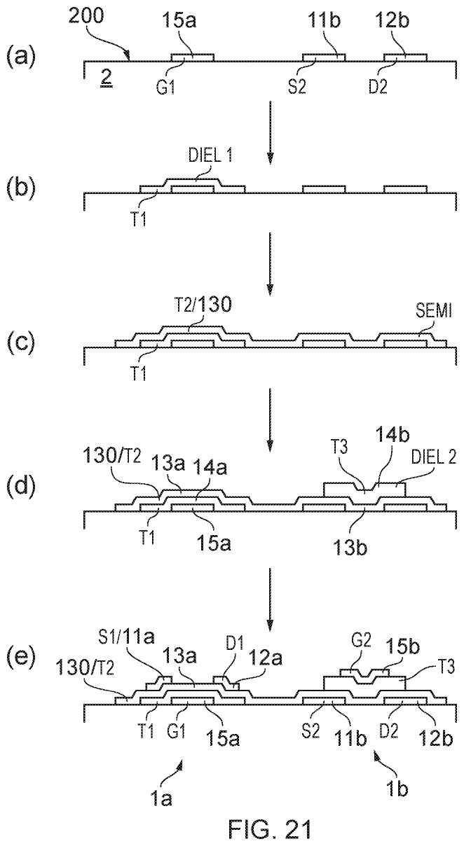

Referring now to FIG. 21, this illustrates steps in the formation of a circuit comprising a plurality of transistors, including one top gate transistor and one bottom gate transistor, those two transistors sharing a semi conductive island. The steps in this method (and others described in this specification) should not necessarily be considered as directly following each other (unless stated as such); in certain embodiments, there may be intermediate steps (e.g. for cleaning or preparation of layers) between at least some of the explicitly described steps. In a first step (a) the bottom gate G1 of the first transistor 1a and the source and drain terminals S2, D2 of the second transistor 1b are provided on a substrate 2. Subsequently, a first thin film T1 of dielectric material is formed over the bottom gate of the first transistor by sALD. In a subsequent step, a shared or common layer of semiconductive material T2/130 is formed by blanket deposition and then patterning (130), or by sALD (T2) (21c). Subsequently, a further thin film or island T3 of dielectric material is formed by sALD to provide the gate dielectric of the second, top gate, device 1b. Finally, the source and drain terminals of the first device 1a and the top gate 15b of the second device 1b are formed by any suitable technique, to arrive at the structure illustrated in FIG. 21e. The plurality of devices manufactured using the method illustrated in FIG. 21 share the same semiconductor material but can have the same or different dielectric materials.

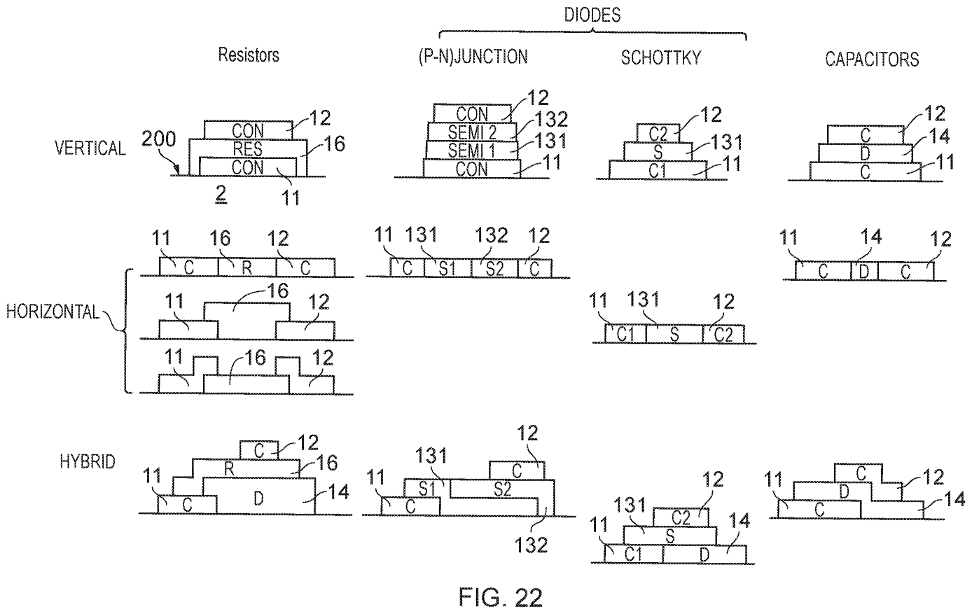

Referring now to FIGS. 22, 25, and 26, these illustrate a variety of devices which can be manufactured using methods embodying the invention, and which may themselves embody aspects of the present invention. In general, each of these devices comprises a plurality of elements, and at least one of those elements has been formed by atomic layer deposition over a limited portion of a substrate. These devices include resistors, generally having a first conductive terminal 11, a second conductive terminal 12, and a layer or body of resistive material 16 providing a resistive path between the terminals 11, 12. The resistors may have a vertical configuration, a horizontal configuration, or a hybrid configuration as shown in the figures. FIG. 22 illustrates horizontal variations with terminals 11, 12 partially overlying resistor body 16 (or/and resistor body 16 partially overlying the terminals). Other variants include those with one terminal overlapping the resistor body, and the resistor body overlapping the other terminal. Similarly, these devices include diodes which may be junction type devices, comprising first and second conductive terminals 11, 12, a first layer or body of semiconductor material 131, and a second layer or body of semiconductor material 132, with the interface between the two semiconductor layers or bodies providing a rectifying interface or junction. These junction diodes may also have vertical, horizontal, or hybrid configurations relative to a supporting substrate for example. Diodes which may embody the invention also include Schottky diodes, generally comprising a first conductive terminal 11 connected to a layer or body of semiconductive material 131 at first interface, and a second conductive terminal 12 connected to the layer or body of semiconductor material 131 at a second interface, with one of these interfaces being a resistive (ohmic) contact and the other of these interfaces being a rectifying or Schottky interface or contact. Again the Schottky diodes may have vertical, horizontal, or hybrid configurations. Additionally, certain embodiments may provide electronic devices in the form of capacitors, generally comprising first and second conductive terminals 11, 12 separated by a layer or body of dielectric material 14, again in vertical, horizontal, or hybrid configurations.

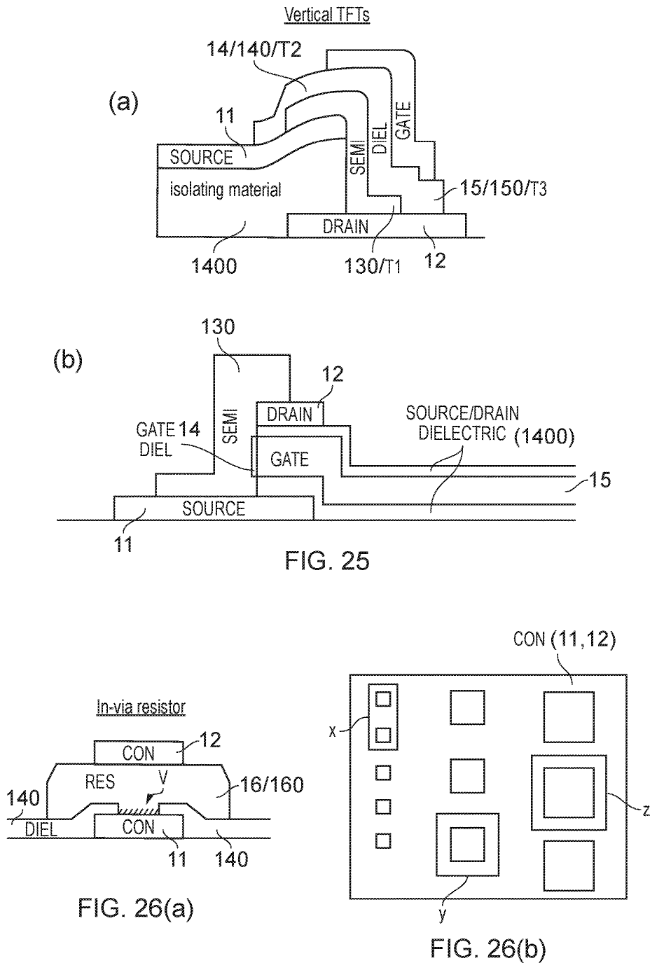

Now referring to FIG. 25, this illustrates varieties of TFTs in a vertical configuration. The first example (FIG. 25 (a)) illustrates source 11 and drain 12 terminals separated vertically by an insulating layer 1400. A first layer of semiconductive material 130 (or T1) is deposited conformally on the source terminal, insulating layer (or isolating material), and drain terminal to partially overlap both terminals and make electrical contact with them. A dielectric layer 140 (or 14 or T2) is deposited conformally to fully cover the semiconductor 130 (T1). A gate terminal 15 (or 150 or T3) is deposited conformally on the dielectric layer so as to not make electrical contact with either of the source and drain terminals 11, 12. In this example, the height of the edge of the source above the drain terminal defines the channel length. Further configurations are shown in FIG. 25 (b) for the vertical TFT, with at least one component formed by atomic layer deposition. A notable advantage of vertical devices is the conformal coverage that atomic layer deposition provides over topography; sidewall coverage is critical for vertical devices.

Now referring to FIG. 26, this illustrates an in-via resistor and a suggested use for such devices. FIG. 26a shows an in-via resistor comprising a first conductive island providing a first terminal 11. A dielectric layer 140 is formed over the first conductive island so as to completely cover the first conductive island. A via V through the dielectric layer is formed over the first conductive island. A resistor layer 16 (or 160) is formed to make electrical contact with the first conductive island at the base of the via, and may to some extent overlap the dielectric layer 140 surrounding the via V. A second conductive island (providing a second terminal 12) is formed on the resistor island 16/160 so as to make electrical contact with the upper and/or lateral surface of the resistor island. Device characteristics are defined in the area of the base of the via, as well as in the properties of the resistor layer, in order to control resistor properties. Certain embodiments may also comprise one or more interconnections that lie on top of the dielectric layer 140 (e.g. directly and/or indirectly). As shown in FIG. 26b, one example of an application of spatially selective ALD in the formation of in-via resistors is using different materials for the dielectric layer within a memory array. Thus, FIG. 26b shows a memory array comprising respective islands x, y, and z, of different dielectric materials

It will be appreciated that the sALD techniques described in this specification to form thin films or islands of material over selected limited portions of a substrate may be used to form one or more of the components of the devices illustrated in FIG. 22. These techniques may be used to form a plurality of the device components, and optionally all of the illustrated components, and form heterojunctions between those components, vertically, horizontally, or in hybrid configurations.

It will also be appreciated that the techniques disclosed in this specification enable the manufacture of thin film ICs to incorporate a range of devices with locally-tuned properties. These devices may, for example, be formed in selectively-deposited islands of semiconducting metal oxide materials. Whilst each island may, in certain embodiments, be many times larger (i.e. in area) than an individual device, it may provide active material for a number of devices. The properties of the semiconductor and/or gate dielectric layers may differ between islands.

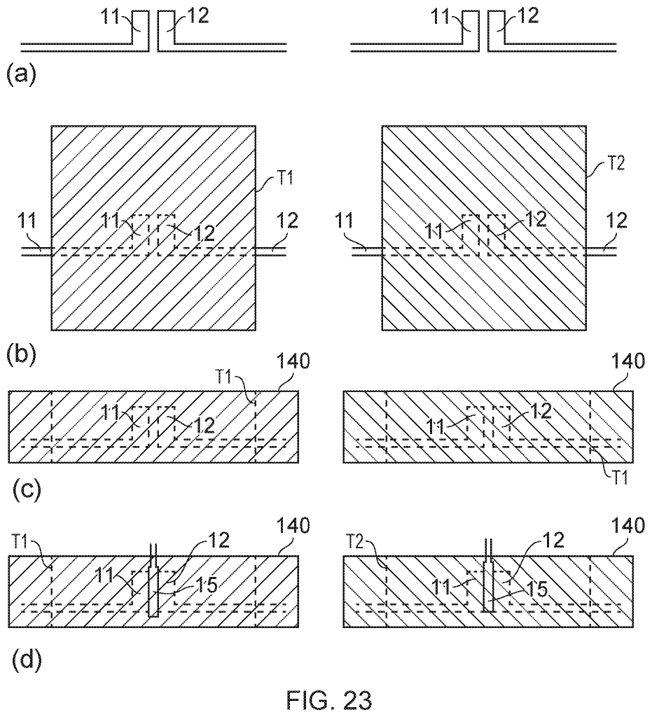

Referring now to FIG. 23, in certain embodiments a circuit may comprise a plurality of transistors (e.g. lateral TFTs) and that circuit (i.e. those transistors) may be formed as illustrated in the figure and described in the flow below.

As shown in FIG. 23a, the lower electrodes of two or more TFTs are deposited and patterned, in this example, using lithographic techniques to provide small device dimensions, for example in the tens or hundreds of nanometres range. In this example the drain and source electrodes 11, 12 of two transistors have been formed, however alternatively, the TFT gate electrodes may be formed first, to provide bottom gate or back gate TFT geometries. The lower electrodes for each TFT may be differently sized, spaced and/or shaped from each other, or alternatively may have the same size/spacing/shape.

As shown in FIG. 23b, separate semiconductor islands T1, T2 are formed over parts of the TFT electrode structures, using a selective deposition technique such as micro-reactor sALD or patterned inhibitor sALD. The islands may be relatively large compared to the channel dimensions of any one transistor, for example each island may have a lateral dimension of the order micrometres to hundreds of micrometres. The two semiconductor islands may have the same or different properties from each other. For example:
one island may be thicker than the other
one island may have a different composition or dopant gradient from the other
one island may be formed as a p-type semiconductor and the other may be formed as an n-type semiconductor, e.g. by using different sALD precursors for the two different islands
one island may be deposited under different temperature, gas flow, plasma or other sALD conditions from the other island
one island may be annealed differently from the other, post-deposition
multiple n-type and/or p-type islands can be deposited, laterally adjacent to each other, to create heterojunctions for devices and/or circuits. For example an island having a single semiconductor layer may act as a TFT channel, whilst an adjacent (abutting, making electrical contact) island having either two similar semiconductor layers, two dissimilar semiconductor layers, or a semiconductor layer and a conducting layer, may form an electrode (source, drain) for that TFT channel.

For bottom gate or back gate TFT geometries a gate oxide layer may be deposited prior to the semiconductor layer.

As shown in FIG. 23c, a gate oxide layer 140 is formed over the semiconductor layer (for the top gate geometry shown), for example as a blanket deposition that is subsequently patterned using lithography. The deposition step may be performed immediately after the semiconductor layer has been deposited, ensuring a clean interface between the two layers. Alternatively the gate oxide layer may be formed using the same selective deposition technique used to form the semiconductor islands, for example by introducing gate dielectric precursors into a micro-reactor SALD tool (i.e. head) immediately after deposition of the semiconductor layer. The semiconductor and gate dielectric layers of one or more of these islands may be deposited with a concentration gradient. That could be through tuning of the reaction, e.g. one area is deposited in saturation (where there is full step coverage or max. layer growth per cycle), whereas other areas could be shorter (e.g. short precursor pulse or reduced amount) so that saturation is not reached. In that way the area with shorter/lower precursor concentration will have less of that specific material present. This could affect doping and/or change electrical properties (insulating/resistive/semiconductive/conductive). The gate oxide patterning step may also pattern the semiconductor layer, improving the electrical isolation of the TFTs. Alternatively the gate oxide layer may be selectively deposited over the semiconductor layer at a coarser level of spatial selectivity, allowing the gate oxide properties to differ between semiconductor islands. In some examples, the gate oxide islands may be selectively deposited over a blanket semiconductor layer. The semiconductor layer may then be patterned by using the gate dielectric as an etch resist, e.g. by selecting an etch process that preferentially removes the semiconductor, leaving the dielectric islands and lower electrodes in place.

Finally, as illustrated in FIG. 23d, the upper electrodes 15 of the two or more TFTs are deposited and patterned over the gate oxide layer (or semiconductor layer, for bottom gate TFT geometries) using lithographic techniques in this example.

Annealing (a thermal treatment) is often employed to enhance the properties of thin film devices. In addition to the conventional approaches of baking the whole wafer at a selected point in manufacture, whether in vacuum or a controlled gas environment, the present techniques encompass local annealing of the semiconductor film, gate oxide film and/or part-formed or fully-formed devices. This may be achieved by a spatially resolved annealing method, for example using an infra-red laser, diode or LED to apply heating to one or more semiconductor/gate dielectric islands. Alternatively or additionally, a spatially-resolved plasma may be applied to activate and/or anneal one or more layers of one or more of the devices, for example by using a microreactor ALD nozzle (or at least part of the head) to selectively anneal certain semiconductor islands. In some cases one island may receive different annealing conditions from another island. Furthermore, the atmosphere adjacent to the semiconductor/gate dielectric islands may be controlled, either locally or over the whole wafer, to include one or more gases during the annealing step. For example the atmosphere may include nitrogen, oxygen or hydrogen, or a mixture such as forming gas (H2/N2). In this way semiconductor/gate dielectric islands may be heated to temperatures up to 400° C.

In this way two TFTs having different properties from each other may be formed, whether from different semiconductor/gate dielectric materials or from the same materials but formed using different conditions or processing. Thus, two or more devices could be made of the same or different materials. If formed of the same materials, those devices could nevertheless have different properties, due to the effects of different processing, e.g. different annealing conditions. Similar or different TFTs may be connected into circuits by conductive tracking, as is well known.

By forming more than one TFT in each semiconductor island, one or more ‘banks’ of each type of TFT may be formed, for example in an array. Such arrays may enable fixed or actively switchable interconnections between TFTs of one or more types, in a similar way as do Field Programmable Gate Arrays (FPGAs).

In one example, p-type TFTs in one island may be connected to n-type TFTs in another island, enabling complementary circuit designs, such as CMOS logic. This may be provided, for example, by forming SnO (p-type) semiconductor in one island and SnO2 (n-type) semiconductor in another island. Alternatively a more radically different material system may be used for each semiconductor island, for example n-type IGZO and p-type SnO. A wide range of semiconductor materials may be formed using spatially selective ALD techniques, and each material may include one or more dopants, and may be formed from one or more nano-laminate layers.

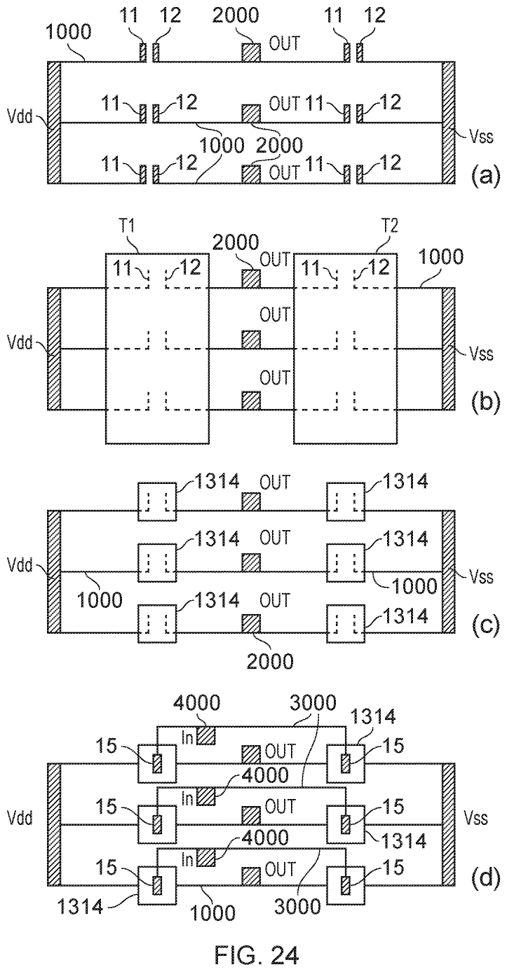

One example of an electronic circuit embodying the invention (and manufactured using a method embodying the invention) includes a p-type TFT island and an n-type TFT island, and steps in its manufacture are illustrated in FIG. 24.

As shown in FIG. 24a, a conductive lower electrode (source-drain) layer is deposited and patterned, e.g. using blanket PVD of one or more metal layers, followed by lithographic patterning and etching. In addition to the electrodes 11,12, conductive tracking 1000 connects the TFTs to each other and to voltage reference rails Vdd and Vss. An output node 2000 is also formed.

As illustrated by FIG. 24b, two semiconductor islands are formed over the TFT electrodes by localised SALD, for example using one or more micro-reactors (or heads). One island is formed from n-type semiconductor and the other from p-type semiconductor.

Then, as shown in FIG. 24c, a gate oxide dielectric layer is deposited as a blanket layer over the semiconductor islands and lower electrode layer. Both the gate dielectric and the semiconductor islands are patterned lithographically and etched as high spatial resolution is required, forming an individual semiconductor and gate dielectric stack 1314 for each TFT.

Finally, as shown in FIG. 24d, a conductive upper (gate) electrode layer is formed over the gate dielectric layer to provide the plurality of respective gate terminals 15, with tracking 3000 connecting the gate electrodes of a p-type TFT and an n-type TFT for each pair. An input node 4000 is also formed.

In certain examples, islands of higher voltage TFTs may be formed in regions of the IC requiring such a specification, such as at input and/or output terminals. This may be enabled by forming a thicker gate oxide dielectric layer in those regions.

A TFT in one semiconductor island may be functionalised differently from one in another island, for example by attaching a layer of receptor molecules onto the upper surface of the gate electrode of a top gate TFT in one semiconductor island, and attaching a different layer (or no layer) of receptor molecules onto the upper surface of the gate electrode of a top gate TFT in another island. Alternatively, functionalisation(s) may be applied to the upper surface of the semiconductor channel of bottom gate TFTs.

In some examples the lower and/or upper electrodes of the TFTs (or indeed electrodes of other devices) may be formed using an area-selective ALD technique as described in this specification. In this way TFTs may be formed entirely using ALD techniques with no lithographic patterning steps.

Vertical TFTs may also be formed, as shown in FIG. 25.

Certain embodiments also provide diodes, PN diodes (with vertical or lateral layer or gradient structures), PIN diodes (with doping density gradient to provide p-type/intrinsic/n-type layers or gradient), capacitors, and resistors (including resistor layers in TFTs, and in-via resistors?

Techniques disclosed in this specification may be used to control thickness gradients to tune properties, and also/alternatively to control composition/doping gradients (laterally and/or vertically) to tune device properties.

Thus, certain techniques may be described as selective deposition combined with property control to create “islands” or “mesas” of functional devices. An advantage of techniques, disclosed herein, utilising sALD is that “print-like” control of deposition over small areas may be achieved.

Thin films deposited over limited substrate portions may, in certain embodiments, be more finely-patterned, after deposition. Domains (e.g. 200×200 um) may thus be produced, with certain properties, and that are then patterned more finely afterwards.

Techniques for thin film deposition may incorporate localised/optimised functionalisation, barrier/interface engineering, and/or localised surface treatment. They may incorporate control of thickness gradients; tweaking thickness may change the “effective doping” profile in the material and changes its properties.

In certain embodiments, active islands of material may be formed, that are deposited directly fully, or formed by deposition followed by a patterning step.

Certain techniques may use ALD to deposit conductors that can be used as SD/Gate electrodes. This can enable an all-ALD device to be manufactured, without needing pattern transfer processes, effectively a wholly additive process (making more efficient use of materials).

In certain embodiments, lateral multiple n and/or p type layers can be deposited (deposited, step nozzle, deposit, etc.) to create heterojunctions for devices and/or circuits.

Activation/annealing can also be done locally, using the localised nozzle plasma (from an sALD head, for example).

It will be appreciated that the techniques disclosed herein may be utilised to form devices incorporating one or more heterojunctions (interfacing arrangements of two dissimilar materials, for example of two different semiconductive materials). Techniques may produce vertically layered n-type and p-type islands, but lateral interfaces are also achievable (side-by-side islands, or a layer partially overlapping another and then planarised to bring it down to a single layer thickness).

Although in certain embodiments all device layers may be formed using ALD, in certain alternative embodiments, some—in particular connections and certain terminals—may need to be lithographically defined. Thus, certain embodiments provide a hybrid method (using some sALD, and some lithography) in order to achieve (i) a reduction in the amount of material that needs to be deposited; instead of forming a blanket layer that is mostly etched away, it is localised into islands to reduce waste, and (ii) a reduction in the number of lithographic patterning steps, each of which consumes time, materials and energy.

Devices embodying the invention include vertical TFTs: these devices tend to require a semiconductor channel layer to be formed on a sidewall of another material (insulator). ALD is very good at forming conformal layers, and may be used here to make islands of semiconductor and, optionally, gate dielectric, over suitable topographies.

Other devices can also be manufactured and take advantage of the conformal coating offered by ALD; examples include in-via resistors and non-planar (‘custom’) resistors.

### Materials

In certain embodiments, the semiconductor material may be a material selected from a list comprising: compound semiconductors (such as GaAs, GaN, InP, CdSe, InGaAs, InGaAsSb), metal oxides such as ZnO, SnO2, NiO, SnO, Cu2O, In2O3, LiZnO, ZnSnO, InSnO (ITO), InZnO (IZO), HfInZnO (HIZO), InGaZnO (IGZO); metal oxynitrides, e.g. ZnxOyNz; inorganic semiconductors (such as amorphous, microcrystalline or nanocrystalline Si); organic semiconductors (such as CuPc, pentacene, PTCDA, methylene blue, Orange G, rubrene); polymer semiconductors (such as PEDOT: PSS, POT, P3OT, P3HT, polyaniline, polycarbazole); 2D materials (such as graphene); chalcogenides such as MoS2, GeSbTe; and perovskites (SrTiO3, CH3NH3PbCl3, H2NCHNH2PbCl3, CsSnI3). These semiconductor materials may also be doped or contain a doping gradient, and may be n-type or p-type.

In certain embodiments, the conductive material may comprise a metal such as Au, Ti, Al, Mo, Pt, Pd, Ag, Cu, Ni, Cr, Ta, W; a metal alloy such as MoNi, MoCr, AlSi; a transparent conductive oxide (such as ITO, IZO, AZO); a metal nitride such as TIN; a carbon material such as carbon black, carbon nanotubes, graphene; a conducting polymer such as polyaniline, PEDOT: PSS; or a semiconductor material.

In certain embodiments, the dielectric material may comprise: a metal oxide such as ZrO2, HfO2, Al2O3, Y2O3, Si3N5, TiO2, Ta2O5; a metal phosphate such as Al2POx; a metal sulphate/sulphite such as HfSOx; a metal nitride such as AlN; a metal oxynitride such as AlOxNy; an inorganic insulator such as SiO2, Si3N4, SiNx; spin on glass (such as polyhydroxybenzyl silsesquioxane, HSQ), polymeric dielectric materials (such as Cytop (a commercially available amorphous fluoropolymer), 1-Methoxy-2-propyl acetate (SU-8), benzocyclobutene (BCB), polyimide, polymethyl methacrylate, polybutyl methacrylate, polyethyl methacrylate, polyvinyl acetate, polyvinyl pyrrolidone, polyvinylphenol, polyvinylchloride, polystyrene, polyethylene, polyvinyl alcohol, polycarbonate, parylene, silicone,); a UV-curable resin; a Nanoimprint resist; or a photoresist. The dielectric material may have a relatively low dielectric constant (low-k, e.g. Cytop, HSQ, parylene) or a relatively high dielectric constant (high-k, e.g. Ta2O5, HfO2).

In certain embodiments, the substrate may be flexible, and/or may comprise one or more layers. The substrate may comprise at least one material selected from a list comprising: glass (rigid or flexible); polymer (e.g. polyethylene naphthalate or polyethylene terephthalate); polymeric foil; paper; insulator coated metal (e.g. coated stainless-steel); cellulose; polymethyl methacrylate; polycarbonate, polyvinylalcohol; polyvinyl acetate; polyvinyl pyrrolidone; polyvinylphenol; polyvinyl chloride; polystyrene; polyethylene naphthalate; polyethylene terephthalate; polyimide, polyamide (e.g. Nylon); poly(hydroxyether); polyurethane; polycarbonate; polysulfone; parylene; polyarylate; polyether ether ketone (PEEK); acrylonitrile butadiene styrene; 1-Methoxy-2-propyl acetate (SU-8); polyhydroxybenzyl silsesquioxane (HSQ); Benzocyclobutene (BCB); Al2O3, SiOxNy; SiO2; Si3N4; UV-curable resin; Nanoimprint resist; photoresist.

In certain embodiments, the resistive material may be any suitable material for providing a resistive current path. Examples of suitable materials include metal oxides, such as ZnO, SnO2, NiO, SnO, Cu2O, In2O3, LiZnO, ZnSnO, InSnO (ITO), InZnO (IZO), HfInZnO (HIZO), InGaZnO (IGZO), AlZnO (AZO). Other suitable materials may include organic materials such as polymers, compound semiconductors, 2D materials such as graphene, and perovskites. A suitable material is one that may be used to form a resistive body, layer, or film depending on its stoichiometry, deposition, processing and/or doping.

In certain embodiments, the providing of a layer or thin film of semiconductor/conductor/resistive/dielectric material, if other than by ALD or sALD, may comprise forming the layer or thin film by a technique selected from a list comprising: vapour deposition (physical e.g. sputter; chemical e.g. PECVD); vacuum deposition (e.g. thermal or e-beam evaporation); coating (spin, dip, blade, bar, spray, slot-die); printing (jet, gravure, offset, screen, flexo); pulsed-laser deposition (PLD).

In certain embodiments, the layer or thin film of semiconductor/conductor/resistive/dielectric material, and/or a surface or surface portion of the substrate, may have surface modification by one or more techniques such as thermal annealing, laser annealing, plasma treatment (such as O2, Cl2, Ar, CF4, BCl3, N2, SF6, HBr), self-assembled monolayers SAM (such as HMDS), reactive ion etching RIE, ozone UV treatment, and doping.

It will be appreciated that certain aspects and embodiments of the present invention provide subject matter in accordance with the following numbered paragraphs:
Paragraph 1. A method of manufacturing at least a first electronic device (1, 1a) comprising a first plurality of components (11, 12, 13, 131, 132, 14, 15, 16) (e.g. a thin film transistor comprising a source terminal, a drain terminal, a semiconductive channel connecting the source terminal to the drain terminal, a gate terminal to which a voltage may be applied to control a conductivity of the semiconductive channel, and a gate dielectric insulating the gate terminal from the semiconductive channel), the method comprising:
   providing a substrate (2) to support the first electronic device, at least during its manufacture;
   selectively depositing over a first limited (bounded) portion (LP1, 201) (i.e. not all) of said substrate, by atomic layer deposition (ALD), a first thin film (T1) (e.g. an island) of conductive, semiconductive, resistive, or dielectric material, said first thin film providing at least one of said first plurality of components (e.g. at least one of: said source terminal; said drain terminal; said gate terminal; said semiconductive channel; and said gate dielectric).
Paragraph 2. A method in accordance with Paragraph 1, further comprising forming at least another one of said first plurality of components on (directly or indirectly) said substrate before selectively depositing said first thin film.
Paragraph 3. A method in accordance with Paragraph 2, wherein said another one is formed at least partly over said first limited portion.
Paragraph 4. A method in accordance with any preceding Paragraph, wherein said depositing by ALD comprises supplying a first precursor (P1) to a first spatial region (or zone) (R1), supplying a second precursor (P2) to a second spatial region (or zone) (R2) separate from the first spatial region, and alternately positioning said first limited portion (201), or parts of said first limited portion, in or under said first region and then in or under said second region.
Paragraph 5. A method in accordance with any preceding Paragraph, wherein said depositing by ALD comprises using an atmospheric-pressure spatial ALD, sALD, technique.
Paragraph 6. A method in accordance with any preceding Paragraph, further comprising forming a patterned layer of inhibitor material (4) over said substrate before said depositing by ALD, the inhibitor material inhibiting said ALD (i.e. inhibiting deposition of said conductive, semiconductive, resistive, or dielectric material by ALD, including by sALD, on the inhibitor material), and the patterned layer of inhibitor material comprising a window (w) over (and defining) said first limited portion of the substrate.
Paragraph 7. A method in accordance with any one of Paragraphs 1 to 5, and comprising no formation of a patterned layer of inhibitor material (4) over said substrate before said depositing by ALD.
Paragraph 8. A method in accordance with Paragraph 4, or any one of Paragraphs 5 to 7 as depending from Paragraph 4, wherein said depositing by ALD comprises:
   using a spatial ALD, sALD, head unit (3) (e.g. print head or shower head) arranged to supply a first ALD precursor (P1) to said first region, said first region being a region adjacent the head unit, a second ALD precursor (P2) to said second region, said second region also being a region adjacent the head unit, and inert gas (I) to at least a third region adjacent to the head unit and separating the first and second regions; and
   effecting relative movement between the substrate and the head unit (e.g. translating the substrate relative to the head unit and/or the head unit relative to the substrate).
Paragraph 9. A method in accordance with Paragraph 8, wherein said effecting of relative movement comprises reciprocating the head unit (3) over said first limited portion (LP1, 201) of the substrate and/or reciprocating said first limited portion of the substrate under the head unit.
Paragraph 10. A method in accordance with Paragraph 8 or Paragraph 9, wherein said effecting of relative movement comprises moving (e.g. scanning) the head unit (3) along a movement (e.g. scanning) path (MP) over said first limited portion of the substrate or moving the substrate relative to the head unit such that the head unit follows said movement path.
Paragraph 11. A method in accordance with any preceding Paragraph, further comprising processing at least a portion of the first thin film to alter at least one of its electronic or electrical properties.
Paragraph 12. A method in accordance with any preceding Paragraph, further comprising selectively depositing over a second limited portion of said substrate, by atomic layer deposition (ALD), a second thin film (T2) of conductive, semiconductive, resistive, or dielectric material, said second thin film providing at least another one of said first plurality of components.
Paragraph 13. A method in accordance with Paragraph 12, wherein said second thin film at least partially covers (e.g. directly, with nothing in-between, or indirectly, with something (for example another layer or layers, and/or another body or bodies) in-between) the first thin film.
Paragraph 14. A method in accordance with Paragraph 12 or Paragraph 13, wherein said second thin film partially overlaps the first thin film and comprises a first portion covering (e.g. directly, with nothing in-between, or indirectly, with something (for example another layer or layers, and/or another body or bodies) in-between) a portion of the first thin film, and a second portion adjacent and not covering the first thin film.
Paragraph 15. A method in accordance with Paragraph 14, further comprising removing said first portion of the second thin film (e.g. to planarise).
Paragraph 16. A method in accordance with Paragraph 12, wherein said second thin film is adjacent and in electrical contact with the first thin film but does not overlap the first thin film.
Paragraph 17. A method in accordance with Paragraph 12, wherein the second thin film does not overlap, and is separate from, the first thin film.
Paragraph 18. A method in accordance with any preceding Paragraph, further comprising forming at least one of said first plurality of components by forming a layer (120, 130, 140, 150, 160) of conductive, semiconductive, resistive, or dielectric material over at least a portion of said substrate and patterning said layer (e.g. by lithography).
Paragraph 19. A method in accordance with any preceding Paragraph, for manufacturing at least said first electronic device (1a) and a second electronic device (1b) comprising a second plurality of components (11b, 12b, 13b, 131b, 132b, 14b, 15b, 16b), wherein said substrate supports the second electronic device, at least during its manufacture, and said first thin film provides at least one of said second plurality of components.
Paragraph 20. A method in accordance with Paragraph 19, wherein said first and second electronic devices are transistors (e.g. bottom gate transistors, top gate transistors, or one is top gate and the other is bottom gate).
Paragraph 21. A method in accordance with Paragraph 20, wherein said first thin film is a thin film of semiconductive material and provides a respective semiconductive channel of each of the first and second devices.
Paragraph 22. A method in accordance with any preceding Paragraph, for manufacturing at least said first electronic device and a third electronic device comprising a third plurality of components, wherein said substrate supports the third electronic device, at least during its manufacture, and the method further comprises selectively depositing over a third limited portion of said substrate, by atomic layer deposition (ALD), a third thin film of conductive, semiconductive, resistive, or dielectric material, said third thin film providing at least one of said third plurality of components.
Paragraph 23. A method in accordance with any preceding Paragraph, wherein each said electronic device is one of: a transistor (e.g. a thin film transistor); a resistor; a diode (e.g. junction or Schottky diode); and a capacitor.
Paragraph 24. A method in accordance with any preceding Paragraph, wherein the first electronic device is a thin film transistor comprising a source terminal, a drain terminal, a semiconductive channel connecting the source terminal to the drain terminal, a gate terminal to which a voltage may be applied to control a conductivity of the semiconductive channel, and a gate dielectric insulating the gate terminal from the semiconductive channel, the method further comprising:
   forming said source and drain terminals on or over (e.g. directly or indirectly on) a surface of said substrate,
   and wherein said first thin film is a thin film of semiconductive material, and said first limited portion is arranged such that the thin film of semiconductive material provides said semiconductive channel (and optionally overlaps at least part of at least one of the source and drain terminals),
   the method further comprising forming a layer of dielectric material covering at least a portion of said thin film of semiconductive material, and forming said gate terminal on said dielectric material, such that at least a portion of the layer of dielectric material provides said gate dielectric.
Paragraph 25. A method in accordance with Paragraph 24, wherein forming said layer of dielectric material comprises forming said layer of dielectric material by a technique other than ALD.
Paragraph 26. A method in accordance with Paragraph 24, wherein forming said layer of dielectric material comprises selectively depositing over a second limited (bounded) portion of said substrate, by atomic layer deposition (ALD), a thin film (e.g. an island) of dielectric material, and said second limited portion is arranged such that the thin film of dielectric material covers at least said semiconductive channel (and optionally overlaps at least part of at least one of the source and drain terminals).
Paragraph 27. A method in accordance with Paragraph 26, wherein said second limited portion is identical to the first limited portion.
Paragraph 28. A method in accordance with Paragraph 26, wherein the second limited portion is different from the first limited portion (e.g. differs from the first limited portion in at least one of size, dimensions, position, and shape).
Paragraph 29. A method in accordance with any one of Paragraphs 24 to 28, further comprising using said gate terminal as an etch mask to remove portions of said thin film of semiconductive material and/or said layer of dielectric material not under said gate terminal.
Paragraph 30. A method in accordance with any one of Paragraphs 24 to 29, further comprising processing at least a portion of said thin film of semiconductive material to change at least one of its electrical properties before forming said layer of dielectric material.
Paragraph 31. A method in accordance with any one of Paragraphs 1 to 23, wherein the first electronic device is a thin film transistor comprising a source terminal, a drain terminal, a semiconductive channel connecting the source terminal to the drain terminal, a gate terminal to which a voltage may be applied to control a conductivity of the semiconductive channel, and a gate dielectric insulating the gate terminal from the semiconductive channel, the method further comprising:
   forming said gate terminal on or over (e.g. directly or indirectly on) a surface of said substrate; and
   forming a layer of dielectric material covering at least said gate terminal (and optionally covering at least one region of the substrate surface adjacent the gate terminal),
   and wherein said first thin film is a thin film (e.g. an island) of semiconductive material, and said first limited portion is arranged such that the thin film of semiconductive material provides at least said semiconductive channel over the gate terminal,
   the method further comprising forming said source and drain terminals, connected by said semiconductive channel.
Paragraph 32. A method in accordance with Paragraph 31, wherein forming said layer of dielectric material comprises forming said layer of dielectric material by a technique other than ALD.
Paragraph 33. A method in accordance with Paragraph 31, wherein forming said layer of dielectric material comprises selectively depositing over a second limited (bounded) portion of said substrate, by atomic layer deposition (ALD), a thin film (e.g. an island) of dielectric material, and said second limited portion is arranged such that the thin film of dielectric material covers at least said gate terminal.
Paragraph 34. A method in accordance with Paragraph 33, wherein said second limited portion is identical to the first limited portion.
Paragraph 35. A method in accordance with Paragraph 33, wherein the second limited portion is different from the first limited portion (e.g. differs from the first limited portion in at least one of size, dimensions, position, and shape).
Paragraph 36. A method in accordance with any one of Paragraphs 31 to 35, further comprising processing said thin film of semiconductive material to change at least one of its electrical properties before forming said source and drain terminals.
Paragraph 37. A method in accordance with any one of Paragraphs 1 to 17, comprising:
   selectively depositing over a plurality of limited (bounded) portions of said substrate, by atomic layer deposition (ALD), a plurality of thin films (e.g. a plurality of islands) of conductive, semiconductive, resistive, or dielectric material, such that each of said first plurality of components is provided by a respective one of said thin films.
Paragraph 38. A method of manufacturing an electronic circuit comprising a first plurality of electronic devices, each device comprising a respective plurality of components, the method comprising:
   providing a substrate to support the first plurality of electronic devices (e.g. to support the entire circuit), at least during their manufacture;
   selectively depositing over a first limited (bounded) portion (i.e. not all) of said substrate, by atomic layer deposition (ALD), a first thin film (e.g. an island) of conductive, semiconductive, resistive, or dielectric material, said first thin film providing at least one of said respective plurality of components of each of said first plurality of electronic devices.
Paragraph 39. A method in accordance with Paragraph 38, wherein the electronic circuit further comprises a second plurality of electronic devices, each comprising a respective plurality of components, and the method further comprises:
   providing said substrate to support the second plurality of electronic devices (e.g. to support the entire circuit), at least during their manufacture;
   selectively depositing over a second limited (bounded) portion (i.e. not all) of said substrate, by atomic layer deposition (ALD), a second thin film (e.g. an island) of conductive, semiconductive, resistive, or dielectric material, said second thin film providing at least one of said respective plurality of components of each of said second plurality of electronic devices.

Thus, certain aspects of the invention make use of differing islands (e.g. the first and second thin films) of relatively low spatial resolution to support different populations (e.g. the first and second pluralities of devices) of relatively higher resolution devices. Certain embodiments utilize the option of patterning (e.g. lithographic patterning) of semiconductive and/or dielectric layers or islands (deposited by ALD) to separate devices in the same island from each other (e.g. as shown in FIG. 24).
Paragraph 40. A method in accordance with Paragraph 38 or Paragraph 39, wherein said first plurality of electronic devices comprises a first plurality of thin film transistors, TFTs, each thin film transistor comprising a respective source terminal, a respective drain terminal, a respective semiconductive channel connecting the source terminal to the drain terminal, a respective gate terminal to which a voltage may be applied to control a conductivity of the semiconductive channel, and a respective gate dielectric insulating the gate terminal from the semiconductive channel,
   wherein said first thin film provides at least one of said source terminal, said drain terminal, said gate terminal, said semiconductive channel, and said gate dielectric of each of the first plurality of TFTs.
Paragraph 41. A method in accordance with Paragraph 40, wherein said first thin film is a thin film of semiconductive material and provides the semiconductive channels of each of the first plurality of TFTs.
Paragraph 42. A method in accordance with Paragraph 41, comprising:
   forming the source and drain terminals of each of the first plurality of TFTs on or over (e.g. directly or indirectly on) a surface of the substrate,
   and wherein said first limited portion is arranged such that the first thin film of semiconductive material provides said semiconductive channel of each of the first plurality of TFTs (and optionally overlaps at least part of at least one of the source and drain terminals of at least one of the first plurality of TFTs),
   the method further comprising forming a layer of dielectric material covering at least a portion of said first thin film of semiconductive material, and forming said gate terminals on said dielectric material, such that a respective portion of the layer of dielectric material provides each said gate dielectric.
Paragraph 43. A method in accordance with Paragraph 42, wherein forming said layer of dielectric material comprises forming said layer of dielectric material by a technique other than ALD.
Paragraph 44. A method in accordance with Paragraph 42, wherein forming said layer of dielectric material comprises selectively depositing over a second limited (bounded) portion of said substrate, by atomic layer deposition (ALD), a thin film (e.g. an island) of dielectric material, and said second limited portion is arranged such that the thin film of dielectric material covers at least the semiconductive channel of each of the first plurality of TFTs (and optionally overlaps at least part of at least one of the source and drain terminals of at least one the first plurality of TFTs).
Paragraph 45. A method in accordance with Paragraph 44, wherein said second limited portion is identical to the first limited portion.
Paragraph 46. A method in accordance with Paragraph 44, wherein the second limited portion is different from the first limited portion (e.g. differs from the first limited portion in at least one of size, dimensions, position, and shape).
Paragraph 47. A method in accordance with any one of Paragraphs 42 to 46, further comprising using each said gate terminal as an etch mask to remove portions of said thin film of semiconductive material and/or said layer of dielectric material not under said gate terminals.
Paragraph 48. A method in accordance with any one of Paragraphs 42 to 47, further comprising processing said first thin film of semiconductive material to change at least one of its electrical properties before forming said layer of dielectric material.
Paragraph 49. A method in accordance with Paragraph 39, or any one of Paragraphs 40 to 48 as depending from Paragraph 39, wherein said second plurality of electronic devices comprises a second plurality of thin film transistors, TFTs, and said second thin film provides at least one of said source terminal, said drain terminal, said gate terminal, said semiconductive channel, and said gate dielectric of each of the second plurality of TFTs.
Paragraph 50. A method in accordance with Paragraph 49, wherein said second thin film is a second thin film of semiconductive material and provides the semiconductive channels of each of the second pluarilty of TFTs.
Paragraph 51. A method in accordance with Paragraph 50, wherein said first thin film and said second thin film differ in at least one property (e.g. electrical and/or electronic property, and/or physical property such as thickness).
Paragraph 52. A method in accordance with any one of Paragraphs 50 to 51, further comprising forming a second layer of dielectric material covering at least a portion of said second thin film of semiconductive material, and forming said gate terminals of the second plurality of TFTs on said second layer of dielectric material, such that a respective portion of the second layer of dielectric material provides each said gate dielectric of the second plurality of TFTs.
Paragraph 53. A method in accordance with Paragraph 52, wherein forming said second layer of dielectric material comprises forming said second layer of dielectric material by a technique other than ALD.
Paragraph 54. A method in accordance with Paragraph 52, wherein forming said second layer of dielectric material comprises selectively depositing by ALD.
Paragraph 55. A method in accordance with Paragraph 54, wherein said first and second layers of dielectric material differ in at least one property (e.g. electrical and/or electronic property, and/or physical property such as thickness).
Paragraph 56. A method of manufacturing an electronic circuit comprising a first electronic device, comprising a first plurality of components, and a second electronic device, comprising a second plurality of components, the method comprising:
   providing a substrate to support the first and second electronic devices, at least during their manufacture;
   selectively depositing over a first limited (bounded) portion (i.e. not all) of said substrate, by atomic layer deposition (ALD), a first thin film (e.g. an island) of conductive, semiconductive, resistive, or dielectric material, said first thin film providing at least one of said first plurality of components of said first electronic device; and
   selectively depositing over a second limited (bounded) portion (i.e. not all) of said substrate, by atomic layer deposition (ALD), a second thin film (e.g. an island) of conductive, semiconductive, resistive, or dielectric material, said second thin film providing at least one of said second plurality of components of said second electronic device.
Paragraph 57. A method in accordance with Paragraph 56, wherein the first electronic device is a first thin film transistor, TFT, and the second electronic device is a second TFT, each thin film transistor comprising a respective source terminal, a respective drain terminal, a respective semiconductive channel connecting the source terminal to the drain terminal, a respective gate terminal to which a voltage may be applied to control a conductivity of the semiconductive channel, and a respective gate dielectric insulating the gate terminal from the semiconductive channel, wherein said first thin film provides at least one of said source terminal, said drain terminal, said gate terminal, said semiconductive channel, and said gate dielectric of the first TFT, and
   said second thin film provides at least one of said source terminal, said drain terminal, said gate terminal, said semiconductive channel, and said gate dielectric of the second TFT.
Paragraph 58. A method in accordance with Paragraph 57, wherein said first thin film is a first thin film of semiconductive material and provides the semiconductive channel of the first TFT, and said second thin film is a second thin film of semiconductive material and provides the semiconductive channel of the second TFT.
Paragraph 59. A method in accordance with Paragraph 58, wherein the first and second thin films of semiconductive material differ in at least one property (e.g. electrical and/or electronic property, and/or physical property such as thickness).
Paragraph 60. A method in accordance with any one of Paragraphs 57 to 59, further comprising forming a first layer of dielectric material to provide the gate dielectric of the first TFT, and forming a second layer of dielectric material to provide the gate dielectric of the second TFT.
Paragraph 61. A method in accordance with Paragraph 60, wherein said first and second layers of dielectric material differ in at least one property (e.g. electrical and/or electronic property, and/or physical property such as thickness).
Paragraph 62. A method in accordance with any one of Paragraphs 57 to 59, further comprising forming a layer of dielectric material over at least a portion of the substrate to provide the gate dielectric of the first and the gate dielectric of the second TFT.
Paragraph 63. A method of manufacturing an electronic circuit, the method comprising:
   providing a substrate (e.g. to support the electronic circuit, at least during its manufacture);
   forming a primary portion of the circuit on or over a primary portion of the substrate; and
   forming a secondary portion of the circuit on or over a secondary portion of the substrate, wherein the secondary portion of the circuit comprises at least a first electronic device comprising a first plurality of components, and forming the secondary portion comprises manufacturing the first electronic device using a method in accordance with any one of Paragraphs 1 to 37, and the or each said limited portion of the substrate is within said secondary portion of the substrate.
Paragraph 64. A method in accordance with Paragraph 63, wherein said primary portion of the circuit comprises an integrated circuit.
Paragraph 65. A method in accordance with Paragraph 63 or Paragraph 64, wherein said secondary portion of the circuit comprises a first plurality of TFTs and a second plurality of TFTs, the TFTs of the first plurality differing from the TFTs of the second plurality in at least one operational characteristic.
Paragraph 66. An electronic device, plurality of electronic devices or electronic circuit manufactured using a method in accordance with any preceding Paragraph.
Paragraph 67. An electronic circuit comprising a first plurality of electronic devices, each device comprising a respective plurality of components, the electronic circuit comprising:
   a first thin film (e.g. an island) of conductive, semiconductive, resistive, or dielectric material, said first thin film providing at least one of said respective plurality of components of each of said first plurality of electronic devices.
Paragraph 68. An electronic circuit in accordance with Paragraph 67, further comprising a second plurality of electronic devices, each comprising a respective plurality of components, and the electronic circuit further comprises:
   a second thin film (e.g. an island) of conductive, semiconductive, resistive, or dielectric material, said second thin film providing at least one of said respective plurality of components of each of said second plurality of electronic devices.
Paragraph 69. An electronic circuit in accordance with Paragraph 67 or Paragraph 68, further comprising a substrate, and wherein the electronic circuit comprises a primary circuit portion formed on or over a primary portion of the substrate, and a secondary circuit portion formed on or over a secondary portion of the substrate,
   wherein the secondary portion of the circuit comprises at least said first plurality of electronic devices and said first thin film.
Paragraph 70. An electronic circuit in accordance with Paragraph 69, wherein said primary portion of the circuit comprises an integrated circuit.
Paragraph 71. An electronic circuit in accordance with any one of Paragraphs 67 to 70, wherein each said thin film has been formed by ALD.

1. A method of manufacturing at least a first electronic device (1, 1a) comprising a first plurality of components (11, 12, 13, 131, 132, 14, 15, 16), the method comprising:
providing a substrate (2) to support the first electronic device, at least during its manufacture;
selectively depositing over a first limited (bounded) portion (LP1, 201) of said substrate, by atomic layer deposition (ALD), a first thin film (T1) of conductive, semiconductive, resistive, or dielectric material, said first thin film providing at least one of said first plurality of components.

2. A method in accordance with claim 1, further comprising forming at least another one of said first plurality of components on said substrate before selectively depositing said first thin film.

3. A method in accordance with claim 2, wherein said another one is formed at least partly over said first limited portion.

4. A method in accordance with any preceding claim, wherein said depositing by ALD comprises supplying a first precursor (P1) to a first spatial region (R1), supplying a second precursor (P2) to a second spatial region (R2) separate from the first spatial region, and alternately positioning said first limited portion (201), or parts of said first limited portion, in or under said first region and then in or under said second region.

5. A method in accordance with any preceding claim, wherein said depositing by ALD comprises using an atmospheric-pressure spatial ALD, sALD, technique.

6. A method in accordance with any preceding claim, further comprising forming a patterned layer of inhibitor material (4) over said substrate before said depositing by ALD, the inhibitor material inhibiting said ALD, and the patterned layer of inhibitor material comprising a window (w) over said first limited portion of the substrate.

7. A method in accordance with any one of claims 1 to 5, and comprising no formation of a patterned layer of inhibitor material (4) over said substrate before said depositing by ALD.

8. A method in accordance with claim 4, or any one of claims 5 to 7 as depending from claim 4, wherein said depositing by ALD comprises:
using a spatial ALD, sALD, head unit (3) arranged to supply a first ALD precursor (P1) to said first region, said first region being a region adjacent the head unit, a second ALD precursor (P2) to said second region, said second region also being a region adjacent the head unit, and inert gas (I) to at least a third region adjacent to the head unit and separating the first and second regions; and
effecting relative movement between the substrate and the head unit.

9. A method in accordance with claim 8, wherein said effecting of relative movement comprises reciprocating the head unit (3) over said first limited portion (LP1, 201) of the substrate and/or reciprocating said first limited portion of the substrate under the head unit.

10. A method in accordance with claim 8 or claim 9, wherein said effecting of relative movement comprises moving the head unit (3) along a movement path (MP) over said first limited portion of the substrate or moving the substrate relative to the head unit such that the head unit follows said movement path.

11. A method in accordance with any preceding claim, further comprising processing at least a portion of the first thin film to alter at least one of its electronic or electrical properties.

12. A method in accordance with any preceding claim, further comprising selectively depositing over a second limited portion of said substrate, by atomic layer deposition (ALD), a second thin film (T2) of conductive, semiconductive, resistive, or dielectric material, said second thin film providing at least another one of said first plurality of components.

13. A method in accordance with claim 12, wherein said second thin film at least partially covers the first thin film.

14. A method in accordance with claim 12 or claim 13, wherein said second thin film partially overlaps the first thin film and comprises a first portion covering a portion of the first thin film, and a second portion adjacent and not covering the first thin film.

15. A method in accordance with claim 14, further comprising removing said first portion of the second thin film.

16. A method in accordance with claim 12, wherein said second thin film is adjacent and in electrical contact with the first thin film but does not overlap the first thin film.

17. A method in accordance with claim 12, wherein the second thin film does not overlap, and is separate from, the first thin film.

18. A method in accordance with any preceding claim, further comprising forming at least one of said first plurality of components by forming a layer (120, 130, 140, 150, 160) of conductive, semiconductive, resistive, or dielectric material over at least a portion of said substrate and patterning said layer.

19. A method in accordance with any preceding claim, for manufacturing at least said first electronic device (1a) and a second electronic device (1b) comprising a second plurality of components (11b, 12b, 13b, 131b, 132b, 14b, 15b, 16b), wherein said substrate supports the second electronic device, at least during its manufacture, and said first thin film provides at least one of said second plurality of components.

20. A method in accordance with claim 19, wherein said first and second electronic devices are transistors.

21. A method in accordance with claim 20, wherein said first thin film is a thin film of semiconductive material and provides a respective semiconductive channel of each of the first and second devices.

22. A method in accordance with any preceding claim, for manufacturing at least said first electronic device and a third electronic device comprising a third plurality of components, wherein said substrate supports the third electronic device, at least during its manufacture, and the method further comprises selectively depositing over a third limited portion of said substrate, by atomic layer deposition (ALD), a third thin film of conductive, semiconductive, resistive, or dielectric material, said third thin film providing at least one of said third plurality of components.

23. A method in accordance with any preceding claim, wherein each said electronic device is one of: a transistor; a resistor; a diode; and a capacitor.

24. A method of manufacturing an electronic circuit comprising a first plurality of electronic devices, each device comprising a respective plurality of components, the method comprising:
providing a substrate to support the first plurality of electronic devices, at least during their manufacture;
selectively depositing over a first limited portion of said substrate, by atomic layer deposition (ALD), a first thin film of conductive, semiconductive, resistive, or dielectric material, said first thin film providing at least one of said respective plurality of components of each of said first plurality of electronic devices.

25. A method in accordance with claim 24, wherein the electronic circuit further comprises a second plurality of electronic devices, each comprising a respective plurality of components, and the method further comprises:
providing said substrate to support the second plurality of electronic devices, at least during their manufacture;
selectively depositing over a second limited portion of said substrate, by atomic layer deposition (ALD), a second thin film of conductive, semiconductive, resistive, or dielectric material, said second thin film providing at least one of said respective plurality of components of each of said second plurality of electronic devices.

26. A method in accordance with claim 24 or claim 25, wherein said first plurality of electronic devices comprises a first plurality of thin film transistors, TFTs, each thin film transistor comprising a respective source terminal, a respective drain terminal, a respective semiconductive channel connecting the source terminal to the drain terminal, a respective gate terminal to which a voltage may be applied to control a conductivity of the semiconductive channel, and a respective gate dielectric insulating the gate terminal from the semiconductive channel,
wherein said first thin film provides at least one of said source terminal, said drain terminal, said gate terminal, said semiconductive channel, and said gate dielectric of each of the first plurality of TFTs.

27. A method in accordance with claim 26, wherein said first thin film is a thin film of semiconductive material and provides the semiconductive channels of each of the first plurality of TFTs.

28. A method in accordance with claim 27, comprising:
forming the source and drain terminals of each of the first plurality of TFTs on or over a surface of the substrate,
and wherein said first limited portion is arranged such that the first thin film of semiconductive material provides said semiconductive channel of each of the first plurality of TFTs,
the method further comprising forming a layer of dielectric material covering at least a portion of said first thin film of semiconductive material, and forming said gate terminals on said dielectric material, such that a respective portion of the layer of dielectric material provides each said gate dielectric.

29. A method in accordance with claim 28, wherein forming said layer of dielectric material comprises forming said layer of dielectric material by a technique other than ALD.

30. A method in accordance with claim 28, wherein forming said layer of dielectric material comprises selectively depositing over a second limited portion of said substrate, by atomic layer deposition (ALD), a thin film of dielectric material, and said second limited portion is arranged such that the thin film of dielectric material covers at least the semiconductive channel of each of the first plurality of TFTs.

31. A method in accordance with any one of claims 28 to 30, further comprising processing said first thin film of semiconductive material to change at least one of its electrical properties before forming said layer of dielectric material.
